(19) United States
(12) Patent Application Publication
(10) Pub. No.: US 2025/0309884 A1
(43) Pub. Date: Oct. 2, 2025

(54) SWITCH DEVICE, LOAD DRIVE SYSTEM, AND SWITCH SYSTEM

(71) Applicant: ROHM CO., LTD., Kyoto-shi (JP)

(72) Inventor: Tetsuo YAMATO, Kyoto-shi (JP)

(21) Appl. No.: 19/090,563

(22) Filed: Mar. 26, 2025

(30) Foreign Application Priority Data
Mar. 27, 2024 (JP) 2024-050690

(51) Int. Cl. H03K 17/0814; H03K 3/3565; H03K 17/14

(52) U.S. Cl. CPC H03K 17/08142; H03K 17/145; H03K 3/3565

(57) ABSTRACT

A switch device has a control circuit that turns on or off an output transistor disposed between two terminals in accordance with a control signal. When an abnormality is detected in an ON period of the output transistor, the control circuit turns off the output transistor or restricts a current value of the output transistor and switches a state of a diagnostic terminal from a first state to a second state, so as to switch a voltage level of the diagnostic terminal from a first level to a second level. During the ON period of the output transistor, when no abnormality is detected and the voltage level of the diagnostic terminal is changed from the first level to the second level, the control circuit turns off the output transistor.

### CROSS-REFERENCE TO RELATED APPLICATIONS

This nonprovisional application claims priority under 35 U.S.C. § 119(a) on Japanese Patent Application No. 2024-050690 filed in Japan on Mar. 27, 2024, the entire contents of which are hereby incorporated by reference.

### BACKGROUND OF THE INVENTION

### Field of the Invention

The present disclosure relates to a switch device, a load drive system, and a switch system.

### Description of Related Art

There is a switch device that turns on or off an output transistor disposed between two terminals responding to an input control signal, so as to conduct or cut off between the two terminals.

### CITATION LIST

### Patent Literature

Patent Document 1: WO2019/065395

### BRIEF DESCRIPTION OF THE DRAWINGS

FIG. 1 is an overall configuration diagram of a load drive system according to an embodiment of the present disclosure.

FIG. 2 is an external perspective view of a switch device according to the embodiment of the present disclosure.

FIG. 3 is a schematic configuration diagram of a vehicle according to the embodiment of the present disclosure.

FIG. 4 is a diagram illustrating a modified communication method of a control signal between an MCU and a plurality of switch devices, according to the embodiment of the present disclosure.

FIG. 5 is a diagram illustrating connection between the MCU and the plurality of switch devices via a communication bus, according to the embodiment of the present disclosure.

FIG. 6 is a diagram illustrating two flags stored in a memory of a control circuit, according to the embodiment of the present disclosure.

FIG. 7 is an overall configuration diagram of a load drive system, according to the embodiment of the present disclosure.

FIG. 8 is a diagram illustrating two flags stored in the memory of the control circuit, according to the embodiment of the present disclosure.

FIG. 9 is a timing chart of the load drive system in a first case, according to the embodiment of the present disclosure.

FIG. 10 is a timing chart of the load drive system in the first case, according to the embodiment of the present disclosure.

FIG. 11 is a timing chart of the load drive system in a second case, according to the embodiment of the present disclosure.

FIG. 12 is a timing chart of the load drive system in the second case, according to the embodiment of the present disclosure.

FIG. 13 is an explanatory diagram of a reference configuration.

FIG. 14 is a configuration diagram related to temperature abnormality detection, according to a second practical example of the embodiment of the present disclosure.

FIG. 15 is a timing chart related to the temperature abnormality detection, according to the second practical example of the embodiment of the present disclosure.

FIG. 16 is a configuration diagram related to the temperature abnormality detection, according to a third practical example of the embodiment of the present disclosure.

FIG. 17 is a timing chart related to the temperature abnormality detection, according to the third practical example of the embodiment of the present disclosure.

### DETAILED DESCRIPTION OF THE PREFERRED EMBODIMENTS

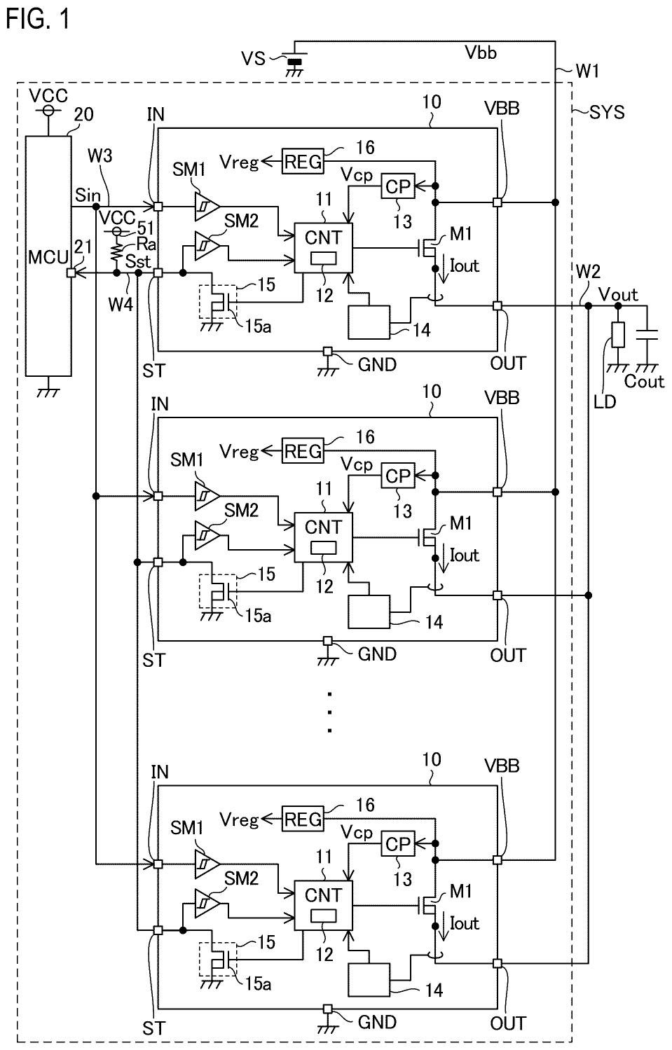

Hereinafter, examples of an embodiment of the present disclosure are described specifically with reference to the drawings. In the drawings that are referred to, the same part is denoted by the same numeral or symbol and overlapping description of the same part is omitted as a rule. Note that in this specification, for simple description, by referring to a symbol or a code of information, a signal, a physical quantity, a functional unit, a circuit, an element, a component, or the like, a name of the information, the signal, the physical quantity, the functional unit, the circuit, the element, the component, or the like may be omitted or abbreviated. For instance, an output wiring denoted by “W2” as described later (see FIG. 1) may be expressed as an output wiring W2, or may be expressed as a wiring W2, and they both indicate the same thing.

First, some terms used in the description of the embodiment of the present disclosure are explained below. A ground means a reference conductive part (reference conductor) having a potential of 0 V (zero volts) to be a reference or means the 0 V potential itself. The reference conductive part may be formed of a conductor such as metal. The 0 V potential may be referred to as a ground potential. The ground potential and a ground voltage have the same meaning. In the embodiment of the present disclosure, a voltage without a specific reference means a potential with reference to the ground.

A level means a potential level, and as for an arbitrary noted signal or voltage, a high level has a higher potential than a low level. As for an arbitrary noted signal or voltage, if the signal or voltage is at high level, it means that the level of the signal or voltage is at high level in a precise sense, and if the signal or voltage is at low level, it means that the level of the signal or voltage is at low level in a precise sense. A level of a signal may be expressed as a signal level, and a level of a voltage may be expressed as a voltage level. In an arbitrary noted signal or voltage, switching from low level to high level may be referred to as a rise edge, and switching from high level to low level may be referred to as a fall edge.

As for an arbitrary signal having a signal level of high level or low level, a period while the signal level is high level is referred to as a high level period, while a period while the signal level is low level is referred to as a low level period. The same is true for an arbitrary voltage having a voltage level of high level or low level.

As for an arbitrary transistor constituted as a field effect transistor (FET) such as a MOSFET, ON state means a conducting state between source and drain of the transistor, while OFF state means a non-conducting state (cut-off state) between source and drain of the transistor. The same is true for a transistor that is not classified as an FET. Unless otherwise noted, MOSFET is understood as an enhancement type MOSFET. MOSFET is an abbreviation of “metal oxide semiconductor field effect transistor”. In addition, unless otherwise noted, in an arbitrary MOSFET, it can be considered that the backgate is short-circuited to the source.

A connection between a plurality of parts forming a circuit, such as arbitrary circuit elements, wirings, nodes, and the like, may be understood to mean an electric connection, unless otherwise noted.

When v1 and v2 are two arbitrary voltages to be compared, “v1>v2” means that the voltage v1 is higher than voltage v2, while “v1<v2” means that the voltage v1 is lower than voltage v2, and “v1=v2” means that the value of the voltage v1 is equal to the value of the voltage v2. The same is true for other expressions including a physical quantity other than a voltage.

FIG. 1 illustrates an overall configuration diagram of a load drive system SYS according to the embodiment of the present disclosure. The load drive system SYS includes a plurality of switch devices 10 and a micro controller unit (MCU) 20, which are main components. The plurality of switch devices 10 are the same ones. The MCU 20 is an example of an external control device that controls operations of the switch devices 10. In addition, the load drive system SYS is equipped with a pull-up resistor Ra. A voltage source VS, a load LD, and an output capacitor Cout are connected to the load drive system SYS. Here, it is considered that the load LD and the output capacitor Cout are external elements of the load drive system SYS, but the load LD and the output capacitor Cout may be understood to be included in the components of the load drive system SYS. In the same manner, the voltage source VS may be considered to be included in the components of the load drive system SYS or may be considered not to be included in the components of the load drive system SYS.

Each of the switch devices 10 includes a power supply terminal VBB, an output terminal OUT, a ground terminal GND, a control input terminal IN, and a diagnostic terminal ST. The power supply terminal VBB and the output terminal OUT may be referred to as a power input terminal and a power output terminal, respectively.

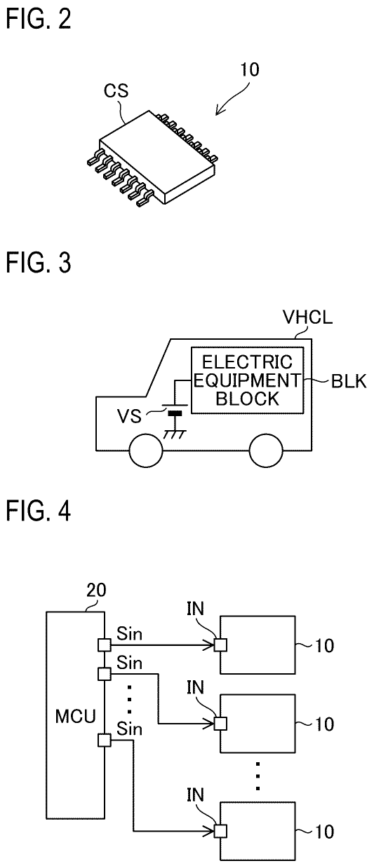

FIG. 2 is an external perspective view of one of the switch devices 10. The switch device 10 is an electronic component including a semiconductor chip having a semiconductor integrated circuit formed on a semiconductor substrate, a case CS (package) housing the semiconductor chip, and a plurality of external terminals exposed from the case CS to the outside of the switch device 10. When the semiconductor chip is enclosed in the case CS made of resin, the switch device 10 is formed. Note that the number of external terminals of the switch device 10 and the type of the case CS of the switch device 10 illustrated in FIG. 2 are merely an example, and they can be designed arbitrarily. Among the above plurality of external terminals provided to the switch device 10, total five external terminals, i.e., the power supply terminal VBB, the output terminal OUT, the ground terminal GND, the control input terminal IN, and the diagnostic terminal ST are illustrated in FIG. 1, but other external terminals can be provided to the switch device 10. Note that the power supply terminal VBB can be constituted of two or more external terminals. The same is true for the output terminal OUT or the ground terminal GND.

The voltage source VS is connected to the ground and an input wiring W1, and outputs a power supply voltage Vbb as a positive DC voltage with respect to the ground. The power supply voltage Vbb is applied to the input wiring W1. The input wiring W1 is a wiring disposed outside of the switch devices 10, and is a wiring connected to the voltage source VS and the power supply terminals VBB of the switch devices 10. The power supply terminals VBB of the switch devices 10 are commonly connected to the input wiring W1, and the common power supply voltage Vbb is applied to the power supply terminals VBB of the switch devices 10.

The output terminals OUT of the switch devices 10 are commonly connected to the output wiring W2, and are connected to the load LD via the output wiring W2. The output capacitor Cout is connected in parallel to the load LD. The voltage at the output terminal OUT is referred to as an output voltage Vout. Therefore, the output voltage Vout is applied to the output wiring W2. The output wiring W2 is a wiring disposed outside of the switch devices 10, and is a wiring connected to the output terminals OUT of the switch devices 10 and the load LD (in detail, it is a wiring for connecting the output terminals OUT of the switch devices 10 with a parallel circuit of the load LD and the output capacitor Cout). A first end of the load LD is connected to the output wiring W2, and a second end of the load LD is connected to the ground. A first end of the output capacitor Cout is connected to the output wiring W2, and a second end of the output capacitor Cout is connected to the ground. The load LD is an arbitrary load that is driven by the output voltage Vout as the power supply voltage.

The ground terminal GND of each switch device 10 is connected to the ground. The control input terminal IN of each switch device 10 is connected to a control wiring W3. The diagnostic terminal ST of each switch device 10 is connected to a diagnosis wiring W4.

The MCU 20 is disposed outside of the switch devices 10. The MCU 20 receives supply of a power supply voltage VCC having a predetermined positive DC voltage value, and is connected to the ground, so as to be driven based on the power supply voltage VCC. The control wiring W3 and the diagnosis wiring W4 are also connected to the MCU 20. A first end of the pull-up resistor Ra is connected to an application terminal 51 of the power supply voltage VCC (a node applied with the power supply voltage VCC), and a second end of the pull-up resistor Ra is connected to the diagnosis wiring W4.

With reference to FIG. 3, in this embodiment, it is supposed that the load drive system SYS is mounted in a vehicle VHCL such as an automobile. In this case, the voltage source VS may be a battery mounted in the vehicle VHCL. An electric equipment block BLK constituted of various types of electric components is mounted in the vehicle VHCL, and components of the electric equipment block BLK include the load drive system SYS, the load LD, and the output capacitor Cout, as well as various types of wirings including the wirings W1 to W4. The load LD includes an electronic control unit (ECU) as well as actuators such as motors, lighting devices, an air conditioner, and the like, which are controlled by the ECU.

The MCU 20 supplies a control signal Sin to each switch device 10 via the control wiring W3. In each switch device 10, the control signal Sin from the MCU 20 is received at the control input terminal IN. In this embodiment, it is supposed that the MCU 20 supplies the common control signal Sin to the control input terminals IN of all the switch devices 10 via the single control wiring W3. For this reason, the control input terminals IN of all the switch devices 10 receive the same control signal Sin. However, as a variation illustrated in FIG. 4, it may be possible that the MCU 20 is connected with the plurality of switch devices 10 via separate control wirings, and that the MCU 20 supplies the control signals Sin to the plurality of switch devices 10, respectively.

The signal on the diagnosis wiring W4 is referred to as a diagnosis signal Sst. The MCU 20 has an input terminal 21 connected to the diagnosis wiring W4 and receives the diagnosis signal Sst at the input terminal 21. The input terminal 21 has a sufficiently high input impedance viewed from the diagnosis wiring W4, and current flowing through the input terminal 21 can be regarded as zero.

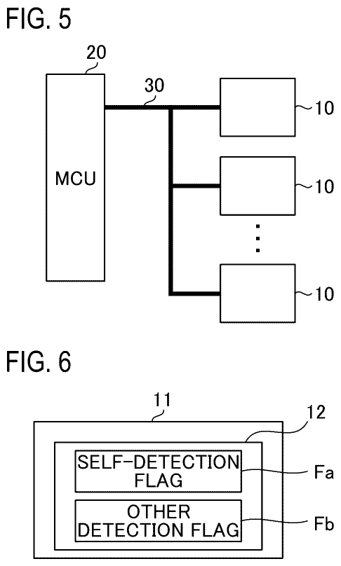

In addition, although not illustrated in FIG. 1 to avoid complicated illustration, the MCU 20 and the switch devices 10 may be connected each other via a communication bus 30 constituted of a plurality of wirings (see FIG. 5). In this case, the MCU 20 and each switch device 10 can bidirectionally communicate with each other via the communication bus 30. The communication between each switch device 10 and the MCU 20 may be parallel communication, but it is supposed in this embodiment that the communication between each switch device 10 and the MCU 20 is serial communication, and that a serial peripheral interface (SPI) is used as an interface for the serial communication. However, the interface for the serial communication between each switch device 10 and the MCU 20 is not limited to SPI, and therefore it may be possible to use an inter-integrated circuit (I²C) or a microwire interface, for example. The MCU 20 can send various types of command signals to each switch device 10 via the communication bus 30. Each switch device 10 can perform an operation or setting designated by the received command signal.

Each switch device 10 includes a group of circuits made of semiconductor, and the group of circuits is housed in the case CS in each switch device 10. In each switch device 10, the group of circuits made of semiconductor includes an output transistor M1, a control circuit 11, a memory 12, a charge pump circuit 13, an abnormality detection circuit 14, a diagnosis output circuit 15, an internal power supply circuit 16, and Schmitt buffers (Schmitt triggers) SM1 and SM2. The memory 12 is built in the control circuit 11. However, it may be possible to understand that the memory 12 is disposed outside of the control circuit 11.

The plurality of switch devices 10 have the same internal structure, and one of the switch devices 10 is noted so as to describe the internal structure of the switch device 10.

The output transistor M1 is constituted of an N-channel type MOSFET. The drain of the output transistor M1 is connected to the power supply terminal VBB, and the source of the output transistor M1 is connected to the output terminal OUT. The drain current of the output transistor M1 is referred to as an output current Iout. Between drain and gate of the output transistor M1, an active clamper (not shown) may be disposed for protecting the output transistor M1 from a counter electromotive voltage generated by an inductive load.

The MCU 20 supplies the control signal Sin to the control input terminal IN. The control signal Sin is a binary signal having a signal level of high level or low level. High level of the control signal Sin is an active level (ON command level), and the control signal Sin of high level is a signal for the MCU 20 to command the switch device 10 and the control circuit 11 to set the output transistor M1 to ON state. Low level of the control signal Sin is a non-active level (OFF command level), and the control signal Sin of low level is a signal for the MCU 20 to command the switch device 10 and the control circuit 11 to set the output transistor M1 to OFF state. The control signal Sin supplied to the control input terminal IN is input to the Schmitt buffer SM1. The Schmitt buffer SM1 shapes the waveform of the control signal Sin input to itself, and outputs the control signal Sin after the waveform shaping to the control circuit 11.

The control circuit 11 is connected to the gate and the source of the output transistor M1, and controls the gate voltage of the output transistor M1 (in other words, controls the gate-source voltage of the output transistor M1) on the basis of the control signal Sin after the waveform shaping, so as to control the state of the output transistor M1. The control signal Sin in the description of operation performed mainly by the control circuit 11 is the control signal Sin after the waveform shaping. However, there is no substantial difference of level of the control signal Sin between before and after the waveform shaping.

As illustrated in FIG. 6, the memory 12 stores and maintains flags Fa and Fb. The memory 12 includes a nonvolatile memory and a volatile memory classified as a register or the like. Each of the flags Fa and Fb has a value of “0” or “1”. The control circuit 11 sets “0” or “1” to values of the flags Fa and Fb separately. The flag Fa is a self-detection flag, and the flag Fb is an other detection flag. Meanings and uses of the flags Fa and Fb will be described later.

On the precondition that the flags Fa and Fb both have the value of “0”, the control circuit 11 supplies an ON voltage Von to the gate of the output transistor M1 during a high level period of the control signal Sin supplied to itself, so as to control and set the output transistor M1 to ON state. The control circuit 11 supplies an OFF voltage Voff to the gate of the output transistor M1 during a low level period of the control signal Sin supplied to itself, so as to control and set the output transistor M1 to OFF state.

A gate threshold value voltage of the output transistor M1 is denoted by symbol “Vg_TH”. The ON voltage Von is higher than a voltage that is higher than a source potential of the output transistor M1 by the gate threshold value voltage Vg_TH. The ON voltage Von may be a drive voltage Vcp described later. The OFF voltage Voff is lower than a voltage that is higher than the source potential of the output transistor M1 by the gate threshold value voltage Vg_TH. A source voltage of the output transistor M1 may be used as the OFF voltage Voff.

The charge pump circuit 13 is connected to the power supply terminal VBB and steps up the power supply voltage Vbb under control by the control circuit 11, so as to generate the drive voltage Vcp that is higher than the power supply voltage Vbb. The drive voltage Vcp is supplied to the control circuit 11. The difference between the drive voltage Vcp and the power supply voltage Vbb is larger than the gate threshold value voltage Vg_TH of the output transistor M1. The control circuit 11 can turn on the output transistor M1 using the drive voltage Vcp. Note that it may also be possible to make a modification by constituting the output transistor M1 using a P-channel type MOSFET, and when adopting this modification, the charge pump circuit 13 is not necessary.

The abnormality detection circuit 14 detects a plurality of types of abnormalities that can occur in the switch device 10. The plurality of types of abnormalities include an overcurrent abnormality in which excessive current flows in the output transistor M1, a temperature abnormality in which temperature or the like of the output transistor M1 is excessive, a low voltage abnormality in which the voltage supplied to the power supply terminal VBB is a low voltage threshold value or lower, an open abnormality in which the output terminal OUT is in open state, and the like. Note that, in order to detect the overcurrent abnormality, a current sensor that detects current flowing in the output transistor M1 (i.e., the output current Iout) is included in the abnormality detection circuit 14. The abnormality detection circuit 14 outputs to the control circuit 11 a signal indicating whether or not an abnormality has been detected. The abnormality detection circuit 14 can output to the control circuit 11 the signal indicating whether or not an abnormality has been detected, for each of the types of abnormalities that can be detected.

The diagnosis output circuit 15 is a circuit that transfers to the MCU 20 a signal indicating that an abnormality has been detected when the abnormality detection circuit 14 has detected an arbitrary abnormality. Specifically, the diagnosis output circuit 15 includes a diagnosis transistor 15a. The diagnosis transistor 15a is an N-channel type MOSFET having an open drain structure. The drain of the diagnosis transistor 15a is connected to the diagnostic terminal ST, and the source of the diagnosis transistor 15a is connected to the ground. The control circuit 11 is connected to the gate of the diagnosis transistor 15a, and controls gate voltage of the diagnosis transistor 15a so as to set the state of the diagnosis transistor 15a to ON or OFF.

The internal power supply circuit 16 is connected to the power supply terminal VBB, and steps down the power supply voltage Vbb with respect to the ground voltage so as to generate an internal power supply voltage Vreg. The internal power supply voltage Vreg has a predetermined positive DC voltage value. Each circuit in the switch device 10 can be driven on the basis of the internal power supply voltage Vreg with respect to the ground potential.

An input terminal of the Schmitt buffer SM2 is connected to the diagnostic terminal ST, and an output terminal of the Schmitt buffer SM2 is connected to the control circuit 11. The Schmitt buffer SM2 shapes the waveform of the diagnosis signal Sst at the diagnostic terminal ST, and outputs the diagnosis signal Sst after the waveform shaping to the control circuit 11. Note that the Schmitt buffer SM2 has a sufficiently high input impedance viewed from the diagnosis wiring W4 and the diagnostic terminal ST, and that current flowing between the diagnosis wiring W4 and the input terminal of the Schmitt buffer SM2 can be regarded as zero.

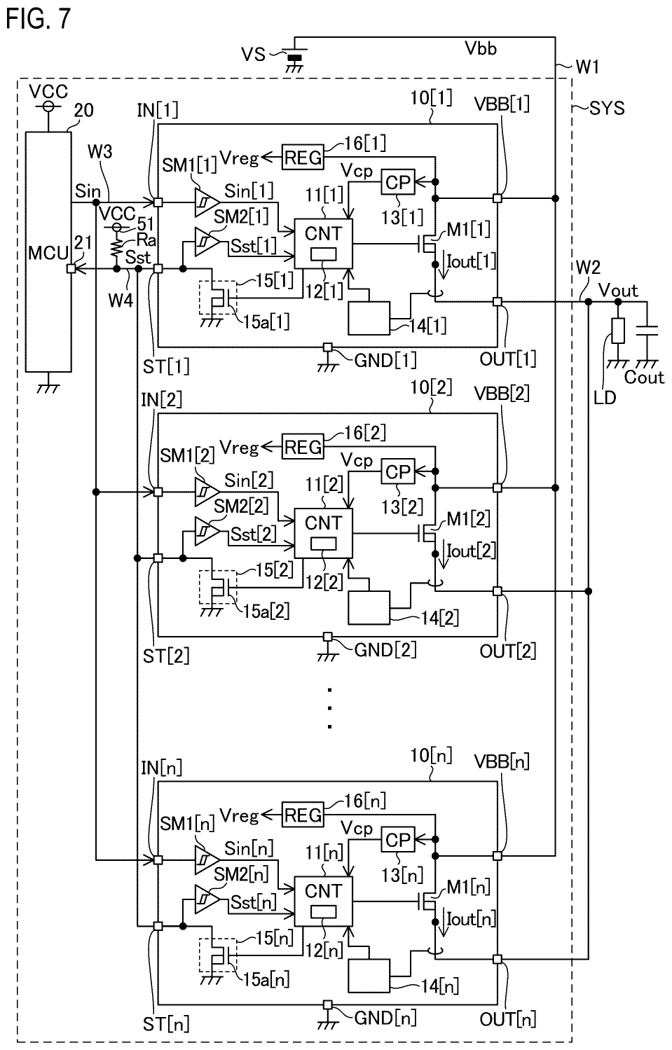

With reference to FIG. 7, in the following description, when expressing the plurality of switch devices 10 in a distinguishable manner from each other, the plurality of switch devices 10 are expressed as the switch devices 10[1] to 10[n]. Here, n indicates an arbitrary integer of two or more, which is equal to the total number of the switch devices 10 disposed in the load drive system SYS. In addition, the output transistor M1, the control circuit 11, the memory 12, the charge pump circuit 13, the abnormality detection circuit 14, the diagnosis output circuit 15, the internal power supply circuit 16, the Schmitt buffer SM1, and the Schmitt buffer SM2 in the switch device 10[i] are particularly expressed as the output transistor M1[i], the control circuit 11[i], the memory 12[i], the charge pump circuit 13[i], the abnormality detection circuit 14[i], the diagnosis output circuit 15[i], the internal power supply circuit 16[i], the Schmitt buffer SM1[i], and the Schmitt buffer SM2[i], respectively. Similarly, the diagnosis transistor 15a in the switch device 10[i] is particularly expressed as the diagnosis transistor 15a[i], and the output current Iout in the switch device 10[i] is particularly expressed as the output current Iout[i]. The power supply terminal VBB, the output terminal OUT, the ground terminal GND, the control input terminal IN, and the diagnostic terminal ST in the switch device 10[i] are particularly expressed as the power supply terminal VBB[i], the output terminal OUT[i], the ground terminal GND[i], the control input terminal IN[i], and the diagnostic terminal ST[i], respectively. Here, i is an arbitrary integer.

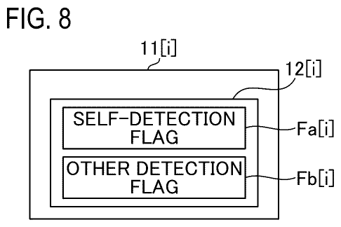

As illustrated in FIG. 8, the flag Fa in the memory 12[i] is particularly expressed as the flag Fa[i], and the flag Fb in the memory 12[i] is particularly expressed as the flag Fb[i]. In the following description, (Fa[i], Fb[i])=(0, 0) means that the flags Fa[i] and Fb[i] both have a value of “0”. (Fa[i], Fb[i])=(1, 0) means that the flag Fa[i] has a value of “1” while the flag Fb[i] has a value of “0”. (Fa[i], Fb[i])=(0, 1) means that the flag Fa[i] has a value of “0” while the flag Fb[i] has a value of “1”. The control circuit 11[i] does not set a value of “1” to both the flag Fa[i] and Fb[i].

Further, an output signal of the Schmitt buffer SM1[i] is referred to as the control signal Sin[i](see FIG. 7). The control signal Sin[i] is substantially the same signal as the control signal Sin at the control input terminal IN[i]. The Schmitt buffer SM1[i] is a buffer circuit having a hysteresis characteristic, and when at least the control signal Sin at the control input terminal IN[i] has a voltage value of the voltage (k_{H}×VCC) or more, it outputs the control signal Sin[i] of high level, while when at least the control signal Sin at the control input terminal IN[i] has a voltage value of the voltage (k_{L}×VCC) or less, it outputs the control signal Sin[i] of low level. Here, k_{H} and k_{L} are coefficients that satisfy “0<k_{L}<k_{H}<1”, and (k_{L}, k_{H})=(0.3, 0.7) holds, for example. On the precondition that the flags Fa and Fb in the memory 12[i] both have a value of “0”, the control circuit 11[i] supplies the ON voltage Von to the gate of the output transistor M1[i] during the high level period of the control signal Sin[i], so as to control and set the output transistor M1[i] to ON state. and the control circuit 11[i] supplies the OFF voltage Voff to the gate of the output transistor M1[i] during the low level period of the control signal Sin[i], so as to control and set the output transistor M1[i] to OFF state.

Further, an output signal of the Schmitt buffer SM2[i] is referred to as the diagnosis signal Sst[i]. The diagnosis signal Sst[i] is substantially the same signal as the diagnosis signal Sst at the diagnostic terminal ST[i]. The Schmitt buffer SM2[i] is a buffer circuit having a hysteresis characteristic, and when at least the diagnosis signal Sst at the diagnostic terminal ST[i] has a voltage value of the voltage (k_{H}×VCC) or more, it outputs the diagnosis signal Sst[i] of high level, while when at least the diagnosis signal Sst at the diagnostic terminal ST[i] has a voltage value of the voltage (k_{L}×VCC) or less, it outputs the diagnosis signal Sst[i] of low level. The Schmitt buffer SM2[i] outputs the diagnosis signal Sst[i] to the control circuit 11[i]. The control circuit 11[i] can perform a unique operation on the basis of the diagnosis signal Sst[i](details are described later).

The power supply terminals VBB[1] to VBB[n] are all commonly connected to the input wiring W1, and the output terminals OUT[1] to OUT[n] are all commonly connected to the output wiring W2. In other words, the output transistors M1[1] to M1[n] are connected in parallel to each other. Therefore, when the output transistors M1[1] to M1[n] are all set to ON state, current flowing through a parallel circuit of the output transistors M1[1] to M1[n](sum current of the output currents Iout[1] to Iout[n]) is supplied to the load LD.

In addition, the diagnostic terminals ST[1] to ST[n] are all commonly connected to the diagnosis wiring W4, and hence the diagnosis transistors 15a[1] to 15a[n] and the pull-up resistor Ra form a so-called wired OR circuit. Depending on states of the diagnosis transistors 15a[1] to 15a[n], the diagnosis signal Sst of the diagnosis wiring W4 has high level or low level. As for the diagnosis signal Sst of the diagnosis wiring W4, high level is substantially the same as a level of the power supply voltage VCC and is at least higher than the voltage (k_{H}×VCC). As for the diagnosis signal Sst of the diagnosis wiring W4, low level is substantially the same as a ground level and is at least lower than the voltage (k_{L}×VCC). Therefore, when the diagnosis signal Sst of the diagnosis wiring W4 has high level, all the diagnosis signals Sst[1] to Sst[n] have high level, while when the diagnosis signal Sst of the diagnosis wiring W4 has low level, all the diagnosis signals Sst[1] to Sst[n] have low level.

The diagnosis output circuit 15[i] is a circuit that controls or sets a state of the diagnostic terminal ST[i]. The state of the diagnostic terminal ST[i] is controlled to be either one of a Hi-Z state and a Lo-Z state. When the diagnosis transistor 15a[i] is in OFF state, the state of the diagnostic terminal ST[i] is the Hi-Z state, while when the diagnosis transistor 15a[i] is in ON state, the state of the diagnostic terminal ST[i] is the Lo-Z state. An input impedance of the diagnostic terminal ST[i] viewed from the diagnosis wiring W4 is far larger when the diagnostic terminal ST[i] is in the Hi-Z state, than when the diagnostic terminal ST[i] is in the Lo-Z state.

When the diagnosis output circuit 15[i] sets the state of the diagnostic terminal ST[i] to the Lo-Z state (i.e., when the diagnosis transistor 15a[i] is in ON state), a current (hereinafter, referred to as a diagnosis current) is generated, which flows from the application terminal 51 of the power supply voltage VCC to the ground via the pull-up resistor Ra, the diagnosis wiring W4, the diagnostic terminal ST[i], and the diagnosis transistor 15a[i]. An input impedance of the diagnostic terminal ST[i] viewed from the diagnosis wiring W4 is far smaller than a value of a pull-down resistor Ra, when the diagnostic terminal ST[i] is in the Lo-Z state. For this reason, during a period while the diagnosis current is generated in any one or more switch devices 10 among the switch devices 10[1] to 10[n] (i.e., during a period while one or more diagnosis transistors 15a among the diagnosis transistors 15a[1] to 15a[n] are in ON state), the diagnosis signal Sst of the diagnosis wiring W4 and the voltage level of each diagnostic terminal ST have low level (i.e., have substantially the ground voltage).

During a period while the diagnosis current is not generated in any one of the switch devices 10[1] to 10[n](i.e., during a period while the diagnosis transistors 15a[1] to 15a[n] are all in OFF state), the diagnosis signal Sst of the diagnosis wiring W4 and the voltage level of each diagnostic terminal ST have high level (i.e., have substantially the level of the power supply voltage VCC). In a case where one switch device 10[i] is noted, when the diagnosis output circuit 15[i] sets the state of the diagnostic terminal ST[i] to the Hi-Z state (i.e., when the diagnosis transistor 15a[i] is in OFF state), the diagnosis current flowing through the diagnosis output circuit 15[i] is cut off, and hence the action of the diagnosis output circuit 15[i] setting the diagnosis signal Sst of the diagnosis wiring W4 and the voltage level of each diagnostic terminal ST to low level is stopped. However, another diagnosis output circuit 15 can set the voltage level of each diagnostic terminal ST to low level.

If the abnormality detection circuit 14[i] has not detected any abnormality, the control circuit 11[i] sets the diagnosis transistor 15a[i] to OFF state, while if the abnormality detection circuit 14[i] has detected an abnormality, it sets the diagnosis transistor 15a[i] to ON state.

In the following description, for convenience of description, it is supposed that “n=2” holds for describing operation of the load drive system SYS, unless otherwise noted.

### [First Case]

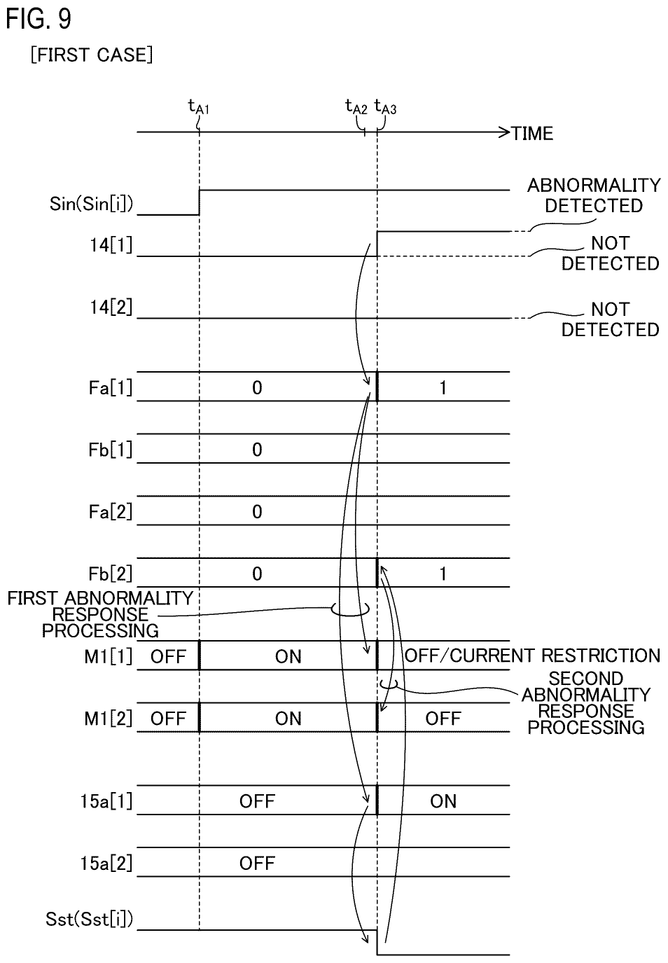

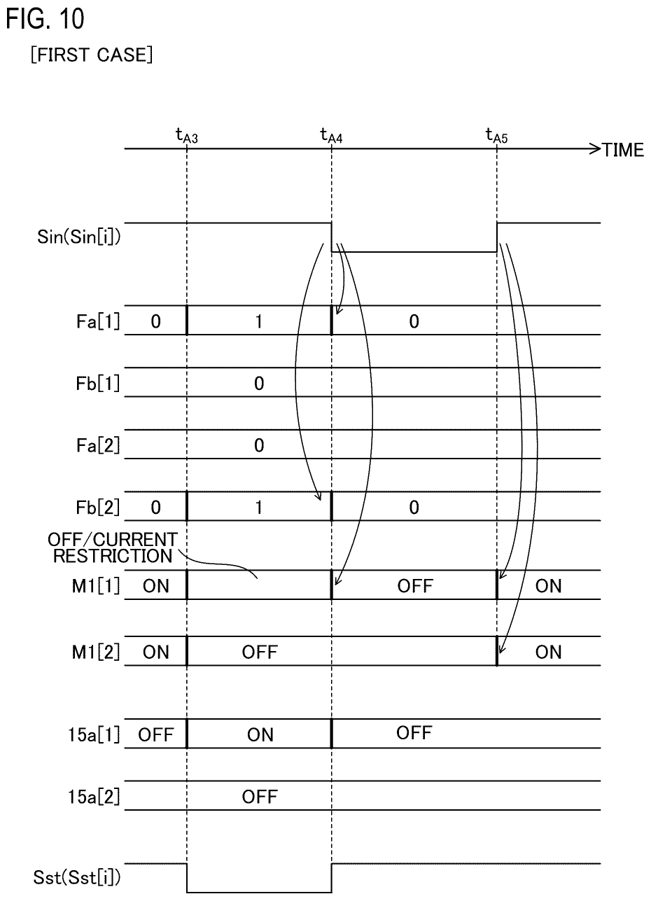

FIGS. 9 and 10 are timing charts of the load drive system SYS in a first case. In the first case, an abnormality is detected only in the abnormality detection circuit 14[1] out of the abnormality detection circuits 14[1] and 14[2].

In each switch device 10, when supply of the power supply voltage Vbb is started, the control circuit 11 performs an initial sequence operation, and hence the switch device 10 becomes an initial state. In the initial state of the switch device 10, the output transistor M1 and the diagnosis transistor 15a are in OFF state, and the values of the flags Fa and Fb are both “0”. Before time point t_{A1} illustrated in FIG. 9, the MCU 20 maintains the control signal Sin to be low level, which is output from itself. At time point t_{A1} after each switch device 10 has finished the initial sequence operation, the MCU 20 generates a rise edge (i.e., switching from low level to high level) in the control signal Sin output from itself, which allows rise edges to be generated also in the control signals Sin[1] and Sin[2].

At time point t_{A1}, (Fa[1], Fb[1])=(0, 0) holds, and hence the control circuit 11[1] responds to the rise edge of the control signal Sin[1], so as to switch the output transistor M1[1] from OFF state to ON state. Similarly at time point t_{A1}, (Fa[2], Fb[2])=(0, 0) holds, and hence the control circuit 11[2] responds to the rise edge of the control signal Sin[2], so as to switch the output transistor M1[2] from OFF state to ON state.

From time point t_{A1} to time point t_{A2} after that, no abnormality is detected in the abnormality detection circuits 14[1] and 14[2]. At time point t_{A3} after a minute time has elapsed from time point t_{A2}, the abnormality detection circuit 14[1] detects an abnormality in the switch device 10[1], and an abnormality detection signal indicating that an abnormality is detected in the switch device 10[1] is transferred from the abnormality detection circuit 14[1] to the control circuit 11[1]. The control circuit 11[1] responds to reception of the abnormality detection signal from the abnormality detection circuit 14[1], so as to set “1” to the flag Fa[1] as the self-detection flag (i.e., to change the value of the flag Fa[1] from “0” to “1”). In this case, the control circuit 11[1] maintains the value of the flag Fb[1] as the other detection flag to be “0”. “Fa[1]=1” indicates that an abnormality is detected first in the switch device 10[1] out of the switch devices 10[1] and 10[2].

During a period while “Fa[1]=1” holds, i.e., during a period while the flag Fa[1] has a value of “1”, the control circuit 11[1] performs first abnormality response processing.

In the first abnormality response processing according to the first case, the control circuit 11[1] can perform an off latch control. The off latch control performed by the control circuit 11[1] is a control of switching the output transistor M1[1] from ON state to OFF state, so as to maintain the output transistor M1[1] to be OFF state without depending on the control signal Sin[1](i.e., even if the control signal Sin[1] is at high level).

Alternatively, in the first abnormality response processing according to the first case, the control circuit 11[1] can perform an intermittent ON/OFF control, on the precondition that the control signal Sin[1] is at high level. When the intermittent ON/OFF control is performed in the first abnormality response processing according to the first case, the control circuit 11[1] first switches the output transistor M1[1] from ON state to OFF state, and then maintains the output transistor M1[1] to be OFF state, or restores ON state of the output transistor M1[1], or alternately turns on and off the output transistor M1[1], in accordance with a type of the detected abnormality and its situation. In any case, similarly to the off latch control, the intermittent ON/OFF control performed by the control circuit 11[1] also includes switching of the output transistor M1[1] to OFF state.

Alternatively, in the first abnormality response processing according to the first case, the control circuit 11[1] can perform a current restriction control on the precondition that the control signal Sin[1] is at high level. The current restriction control performed by the control circuit 11[1] maintains the output transistor M1[1] to be ON state while the value of the output current Iout[1] is restricted to a predetermined limit value I_{LIM} or less.

In addition, in the first abnormality response processing according to the first case, the control circuit 11[1] sets the diagnosis transistor 15a[1] to ON state. Thus, at time point t_{A3} (in a precise sense, after a minute time has elapsed from time point t_{A3}), a fall edge (i.e., switching from high level to low level) is generated in the diagnosis signal Sst on the signal wiring W4 as well as the diagnosis signals Sst[1] and Sst[2]. In other words, in the first abnormality response processing according to the first case, the control circuit 11[1] switches the state of the diagnostic terminal ST[1] from the Hi-Z state to the Lo-Z state using the diagnosis output circuit 15[1], so as to switch the voltage level of the diagnostic terminal ST[1] from high level (the level of the power supply voltage VCC) to low level (the ground level).

In the first case, responding to the fall edge generated in the diagnosis signal Sst[2], the control circuit 11[2] sets “1” to the flag Fb[2] as the other detection flag (i.e., switches the value of the flag Fb[2] from “0” to “1”). In this case, the control circuit 11[2] maintains the value of the flag Fa[2] as the self-detection flag to be “0”. “Fb[2]=1” indicates that, before the switch device 10[2] detects an abnormality, another switch device 10 (here, the switch device 10[1]) has detected an abnormality.

The control circuit 11[2] performs second abnormality response processing during a period while “Fb[2]=1” holds, i.e., during a period while the flag Fb[2] has a value of “1”. In the second abnormality response processing according to the first case, the control circuit 11[2] performs the off latch control. The off latch control performed by the control circuit 11[2] is a control of switching the output transistor M1[2] from ON state to OFF state, so as to maintain the output transistor M1[2] to be OFF state without depending on the control signal Sin[2](i.e., even if the control signal Sin[2] is at high level).

The control circuit 11[2] according to the first case maintains the output transistor M1[2] to be OFF state until a predetermined error release condition is satisfied, after switching the output transistor M1[2] to OFF state by the second abnormality response processing. In other words, the off latch control performed by the control circuit 11[2] is stopped when the error release condition is satisfied. The error release condition for the control circuit 11[2] is satisfied when the level of the control signal Sin[2] is changed from high level (ON command level) to low level (OFF command level). In the first case, at time point t_{A4} after time point t_{A3} (see FIG. 10), a fall edge is generated in the control signal Sin output from the MCU 20, and hence the error release condition is satisfied.

After the second abnormality response processing is started, when the error release condition is satisfied at time point t_{A4}, the control circuit 11[2] according to the first case finishes the second abnormality response processing (i.e., stops the off latch control for maintaining the output transistor M1[2] to be OFF state), and switches the value of the flag Fb[2] from “1” to “0” (see FIG. 10). Therefore, at time point t_{A5} after time point t_{A4}, when a rise edge is generated in the control signal Sin output from the MCU 20 so that a rise edge is generated in the control signal Sin[2](i.e., when the level of the control signal Sin is set to high level), the control circuit 11[2] responds to the rise edge in the control signal Sin[2], so as to switch the output transistor M1[2] from OFF state to ON state again. Note that the control circuit 11[2] always maintains the diagnosis transistor 15a[2] to be OFF state when the control signal Sin[2] is at low level.

On the other hand, according to the first case, the control circuit 11[1] continues the first abnormality response processing until a predetermined error release condition is satisfied after time point t_{A3}. The error release condition for the control circuit 11[1] is satisfied when the level of the control signal Sin[1] is changed from high level (ON command level) to low level (OFF command level). In the first case, at time point t_{A4} after time point t_{A3} (see FIG. 10), a fall edge is generated in the control signal Sin output from the MCU 20, and hence the error release condition is satisfied. When the level of the control signal Sin[1] becomes low level at time point t_{A4}, the control circuit 11[1] finishes the first abnormality response processing, and maintains the output transistor M1[1] to be OFF state, or switches the output transistor M1[1] from ON state to OFF state. In addition, after starting the first abnormality response processing, when the error release condition is satisfied at time point t_{A4}, the control circuit 11[1] according to the first case switches the value of the flag Fa[1] from “1” to “0”. Therefore, at time point t_{A5} after that, when a rise edge is generated on the level of the control signal Sin output from the MCU 20 so that a rise edge is generated in the control signal Sin[1](i.e., when the level of the control signal Sin is set to high level), the control circuit 11[1] responds to the rise edge of the control signal Sin[1], so as to switch the output transistor M1[1] from OFF state to ON state again. Note that the control circuit 11[1] always maintains the diagnosis transistor 15a[1] to be OFF state when the control signal Sin[1] is at low level.

### [Second Case]

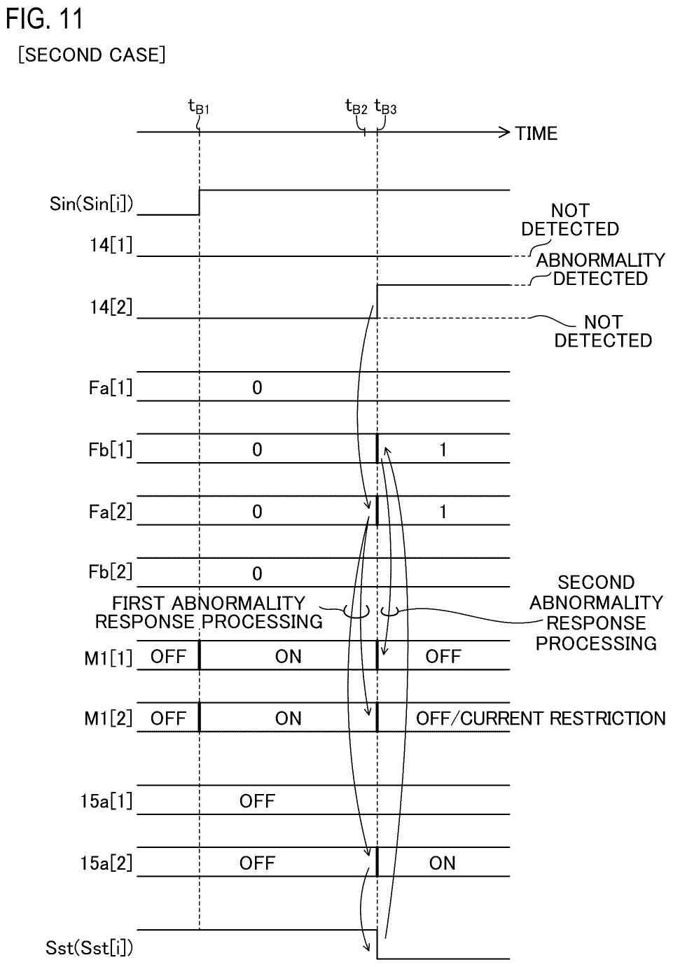

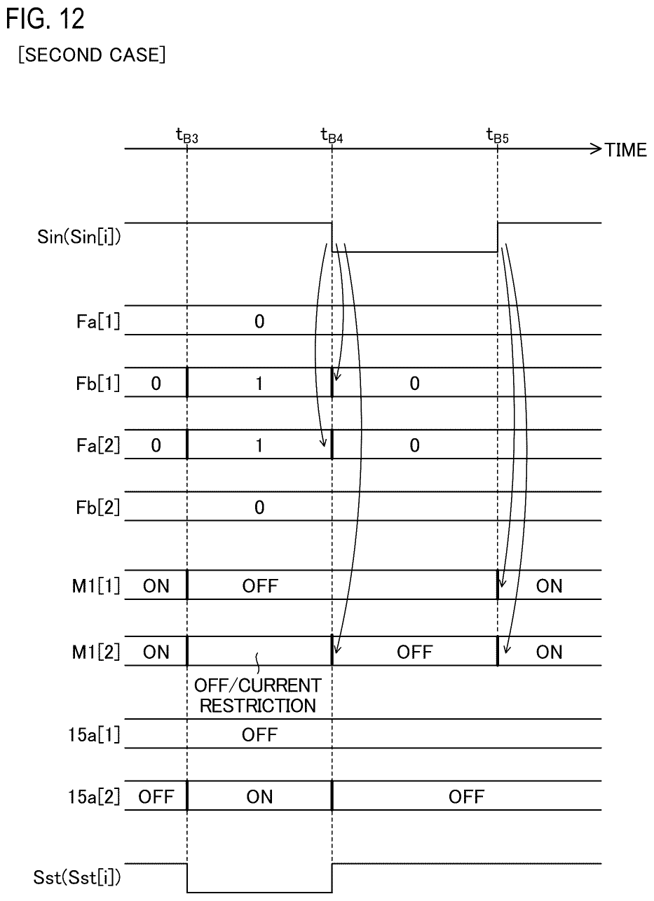

FIGS. 11 and 12 are timing charts of the load drive system SYS according to a second case. In the second case, an abnormality is detected only in the abnormality detection circuit 14[2] out of the abnormality detection circuits 14[2] and 14[1].

When supply of the power supply voltage Vbb is started in the switch devices 10, the control circuit 11 performs the initial sequence operation, and the switch devices 10 become the initial state. In the initial state of the switch device 10, the output transistor M1 and the diagnosis transistor 15a are in OFF state, and the values of the flags Fa and Fb are both “0”. Before time point t_{B1} illustrated in FIG. 11, the MCU 20 maintains the control signal Sin output from itself to be low level. At time point t_{B1} after the initial sequence operation is completed in the switch devices 10, the MCU 20 generates a rise edge in the control signal Sin output from itself, which allows rise edges to be generated also in the control signals Sin[1] and Sin[2].

Because (Fa[1], Fb[1])=(0, 0) holds at time point t_{B1}, the control circuit 11[1]responds to the rise edge of the control signal Sin[1] so as to switch the output transistor M1[1] from OFF state to ON state. Similarly, because (Fa[2], Fb[2])=(0, 0) holds at time point t_{B1}, the control circuit 11[2] responds to the rise edge of the control signal Sin[2] so as to switch the output transistor M1[2] from OFF state to ON state.

From time point t_{B1} to time point t_{B2} after that, no abnormality is detected in the abnormality detection circuits 14[1] and 14[2]. At time point t_{B3} after a minute time has elapsed from time point t_{B2}, the abnormality detection circuit 14[2] detects an abnormality in the switch device 10[2], and an abnormality detection signal indicating that an abnormality is detected in the switch device 10[2] is transferred from the abnormality detection circuit 14[2] to the control circuit 11[2]. The control circuit 11[2] responds to reception of the abnormality detection signal from the abnormality detection circuit 14[2], so as to set “1” to the flag Fa[2] as the self-detection flag (i.e., to change the value of the flag Fa[2] from “0” to “1”). In this case, the control circuit 11[2] maintains the value of the flag Fb[2] as the other detection flag to be “0”. “Fa[2]=1” indicates that an abnormality is detected first in the switch device 10[2] out of the switch devices 10[1] and 10[2].

During a period while “Fa[2]=1” holds, i.e., during a period while the flag Fa[2] has a value of “1”, the control circuit 11[2] performs the first abnormality response processing.

In the first abnormality response processing according to the second case, the control circuit 11[2] can perform the off latch control. The off latch control performed by the control circuit 11[2] is a control of switching the output transistor M1[2] from ON state to OFF state, so as to maintain the output transistor M1[2] to be OFF state without depending on the control signal Sin[2](i.e., even if the control signal Sin[2] is at high level).

Alternatively, in the first abnormality response processing according to the second case, the control circuit 11[2] can perform the intermittent ON/OFF control on the precondition that the control signal Sin[2] is at high level. When the intermittent ON/OFF control is performed in the first abnormality response processing according to the second case, the control circuit 11[2] first switches the output transistor M1[2] from ON state to OFF state, and then maintains the output transistor M1[2] to be OFF state, or restores ON state of the output transistor M1[2], or alternately turns on and off the output transistor M1[2], in accordance with a type of the detected abnormality and its situation. In any case, similarly to the off latch control, the intermittent ON/OFF control performed by the control circuit 11[2] also includes switching of the output transistor M1[2] to OFF state.

Alternatively, in the first abnormality response processing according to the second case, the control circuit 11[2] can perform the current restriction control on the precondition that the control signal Sin[2] is at high level. The current restriction control performed by the control circuit 11[2] maintains the output transistor M1[2] to be ON state while the value of the output current Iout[2] is restricted to a predetermined limit value I_{LIM} or less.

In addition, the first abnormality response processing according to the second case, the control circuit 11[2] sets the diagnosis transistor 15a[2] to ON state. Thus, at time point t_{B3} (in a precise sense, after a minute time has elapsed from time point t_{B3}), a fall edge is generated in the diagnosis signal Sst on the signal wiring W4 as well as the diagnosis signals Sst[1] and Sst[2]. In other words, in the first abnormality response processing according to the second case, the control circuit 11[2] switches the state of the diagnostic terminal ST[2] from the Hi-Z state to the Lo-Z state using the diagnosis output circuit 15[2], so as to switch the voltage level of the diagnostic terminal ST[2] from high level (the level of the power supply voltage VCC) to low level (the ground level).

In the second case, responding to the fall edge generated in the diagnosis signal Sst[1], the control circuit 11[1] sets “1” to the flag Fb[1] as the other detection flag (i.e., switches the value of the flag Fb[1] from “0” to “1”). In this case, the control circuit 11[1] maintains the value of the flag Fa[1] as the self-detection flag to be “0”. “Fb[1]=1” indicates that, before the switch device 10[1] detects an abnormality, another switch device 10 (here, the switch device 10[2]) has detected an abnormality.

The control circuit 11[1] performs the second abnormality response processing during a period while “Fb[1]=1” holds, i.e., during a period while the flag Fb[1] has a value of “1”. In the second abnormality response processing according to the second case, the control circuit 11[1] performs the off latch control. The off latch control performed by the control circuit 11[1] is a control of switching the output transistor M1[1] from ON state to OFF state, so as to maintain the output transistor M1[1] to be OFF state without depending on the control signal Sin[1](i.e., even if the control signal Sin[1] is at high level).

The control circuit 11[1] according to the second case maintains the output transistor M1[1] to be OFF state until a predetermined error release condition is satisfied, after switching the output transistor M1[1] to OFF state by the second abnormality response processing. In other words, the off latch control performed by the control circuit 11[1] is stopped when the error release condition is satisfied. The error release condition for the control circuit 11[1] is satisfied when the level of the control signal Sin[1] is changed from high level (ON command level) to low level (OFF command level). In the second case, at time point t_{B4} after time point t_{B3} (see FIG. 12), a fall edge is generated in the control signal Sin output from the MCU 20, and hence the error release condition is satisfied.

After the second abnormality response processing is started, when the error release condition is satisfied at time point t_{B4}, the control circuit 11[1] according to the second case finishes the second abnormality response processing (i.e., stops the off latch control for maintaining the output transistor M1[1] to be OFF state), and switches the value of the flag Fb[1] from “1” to “0” (see FIG. 12). Therefore, at time point tBs₅ after time point t_{B4}, when a rise edge is generated in the control signal Sin output from the MCU 20 so that a rise edge is generated in the control signal Sin[1](i.e., when the level of the control signal Sin is set to high level), the control circuit 11[1] responds to the rise edge in the control signal Sin[1], so as to switch the output transistor M1[1] from OFF state to ON state again. Note that the control circuit 11[1] always maintains the diagnosis transistor 15a[1] to be OFF state when the control signal Sin[1] is at low level.

On the other hand, the control circuit 11[2] according to the second case continues the first abnormality response processing until a predetermined error release condition is satisfied after time point t_{B3}. The error release condition for the control circuit 11[2] is satisfied when the level of the control signal Sin[2] is changed from high level (ON command level) to low level (OFF command level). In the second case, at time point t_{B4} after time point t_{B3} (see FIG. 12), a fall edge is generated in the control signal Sin output from the MCU 20, and hence the error release condition is satisfied. When the level of the control signal Sin[2] becomes low level at time point t_{B4}, the control circuit 11[2] finishes the first abnormality response processing and maintains the output transistor M1[2] to be OFF state, or switches the output transistor M1[2] from ON state to OFF state. In addition, the control circuit 11[2] according to the second case switches the value of the flag Fa[2] from “1” to “0”, when the error release condition is satisfied at time point t_{B4} after starting the first abnormality response processing. Therefore, at time point t_{B5} after that, when a rise edge is generated in the level of the control signal Sin output from the MCU 20 so that a rise edge is generated in the control signal Sin[2](i.e., when the level of the control signal Sin is set to high level), the control circuit 11[2] responds to the rise edge of the control signal Sin[2], so as to switch the output transistor M1[2] from OFF state to ON state again. Note that the control circuit 11[2] always maintains the diagnosis transistor 15a[2] to OFF state when the control signal Sin[2] is at low level.

### [Consideration Including Description of Reference Configuration]

When performing supply and cutoff of power to the load using a semiconductor switching element (corresponding to the output transistor M1), the switching element is required to have a small ON resistance as much as possible. If power can be supplied to the load through a parallel circuit of a plurality of switching elements, the total ON resistance can be reduced. However, it is usually difficult or hardly recommended to use switch devices in parallel, each of which has a switching element. (The switch device mentioned here is different from the switch device 10, and is referred to as a reference switch device in the following description.) It is because a threshold value of overcurrent protection, overheat protection, or the like is different among the plurality of reference switch devices, which may cause an operation malfunction.

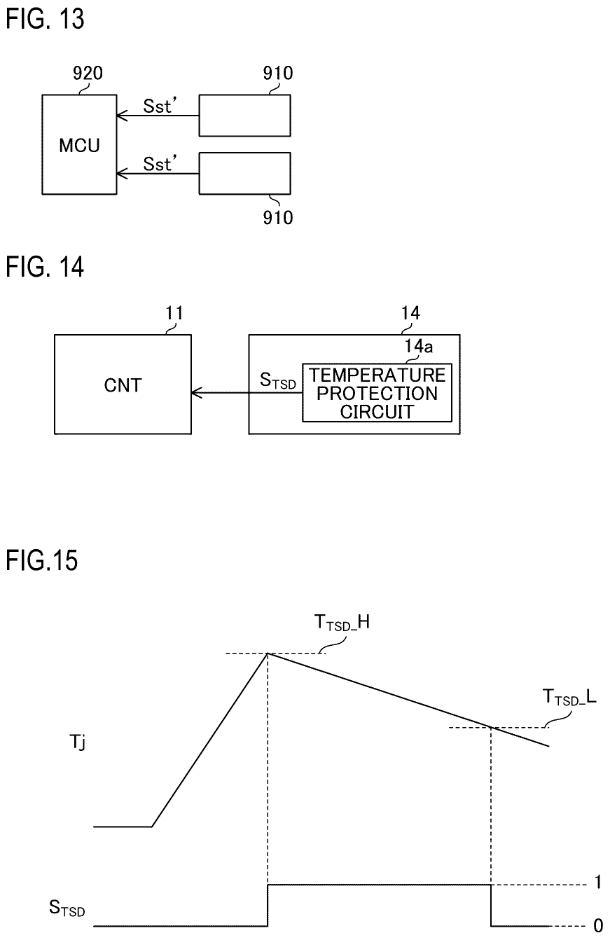

For instance, if two reference switch devices are used by connecting them in parallel, because of a difference in the threshold value of the overcurrent protection, the overheat protection, or the like, it may occur that an abnormality is detected and the protection operation is performed in one of the reference switch devices, and that no abnormality is detected so that the normal operation is continued in the other reference switch device. In this case, in the reference switch device that continues the normal operation, more current flows than usual, and hence an abnormality (such as the overcurrent abnormality) can be detected with high probability after a while. However, the abnormality detection and the protection operation in the two reference switch devices are performed separately and independently. Therefore, as illustrated in FIG. 13, in the reference configuration, in which the switch devices 910 as the two reference switch devices supply the diagnosis signals Sst′ to an MCU 920 separately and independently, the MCU 920 can hardly grasp accurate situation of the load side, and system design becomes complicated.

Therefore, in a system that is required to have a pretty low ON resistance, it is common to prepare a plurality of switching elements as discrete components, to prepare another controller for controlling drives of the discrete components (switching elements), and to adopt a circuit structure in which the plurality of discrete components are connected in parallel to each other. However, this circuit structure increases the number of components and has a disadvantage in cost. In addition, difficulty in substrate layout design is also increased.

In contrast, in the load drive system SYS according to this embodiment, among the plurality of switch devices 10, the switch device 10 that has first detected an abnormality works mainly to send to the MCU 20 an error signal (the diagnosis signal Sst of low level on the diagnosis wiring W4). For this reason, the MCU 20 can accurately and simply recognize a state of a switch device group (10[1] to 10[n]) that drives the load LD, by referring to the diagnosis signal Sst transferred via the diagnosis wiring W4. Because sufficiently low ON resistance can be achieved using the switch device 10 as an electronic component including the output transistor M1, compared with a circuit structure using discrete components, the number of components and cost can be reduced, and further it is expected to facilitate the substrate layout design.

The load drive system SYS is designed to drive the load LD with the switch device group consisting of n switch devices 10, and hence a state where an abnormality is detected in a specific switch device 10 corresponds to a state where an abnormality has occurred in the switch device group. In the state where an abnormality has occurred in the switch device group (i.e., in a state where the load LD is not driven as designed), if another switch device 10 continues its operation independently of the occurrence of abnormality in the specific switch device 10, an unexpected trouble may occur resulting in an undesired situation (operation of the entire switch device group becomes unstable, i.e., stability of operation of the switch device group is deteriorated). Considering this, in the structure according to this embodiment, when an abnormality is detected in a specific switch device 10, this fact is transferred to other switch devices 10 via the diagnostic terminals ST, so as to latch the output transistors M1 in the other switch devices 10 to be OFF. For this reason, the fear described above is cast aside.

Note that unlike the first or second case, in a third case where the abnormality detection circuits 14[1] and 14[2] have simultaneously detected abnormalities, the control circuit 11[1] sets “1” to the flag Fa[1], and independently the control circuit 11[2] sets “1” to the flag Fa[2]. For this reason, after the abnormality detection circuits 14[1] and 14[2] simultaneously detected abnormalities, the control circuit 11[1] performs first abnormality response operation, and independently thereof, the control circuit 11[2] also performs the first abnormality response operation. Also in the third case, the single error signal is supplied to the MCU 20, and hence no particular problem occurs.

Hereinafter, some specific operation examples, applied technology, modified technology, and the like related to the load drive system SYS or the switch device 10 are described in a plurality of practical examples. The matters described above in this embodiment are applied to the following practical examples, unless otherwise noted, and unless any contradiction arises. In each practical example, if there is a matter inconsistent with the above description, the matter described in each practical example may be prioritized. In addition, among the plurality of practical examples described below, a matter described in an arbitrary practical example may be applied to any other practical example, unless any contradiction arises (i.e., among the plurality of practical examples, any two or more practical examples can be combined).

### First Practical Example

A first practical example is described. The plurality of types of abnormalities that can be detected by the abnormality detection circuit 14 include the overcurrent abnormality. In the first practical example, it is supposed that the abnormality that can be detected by the abnormality detection circuit 14 is the overcurrent abnormality.

As described above, the abnormality detection circuit 14 includes the current sensor that detects current flowing in the output transistor M1 (i.e., the output current Iout). In each switch device 10, the abnormality detection circuit 14 compares the value of the output current Iout detected by the current sensor with a predetermined overcurrent threshold value I_{TH}, so as to determine whether or not the overcurrent abnormality has occurred.

In each switch device 10, the abnormality detection circuit 14 determines that the overcurrent abnormality has occurred if the value of the output current Iout is the overcurrent threshold value I_{TH} or more. Therefore, the abnormality detection circuit 14[1] according to the first case (see FIG. 9) determines that the overcurrent abnormality has occurred, when the value of the output current Iout[1] that is the overcurrent threshold value I_{TH} or more is detected at time point t_{A3}, and outputs to the control circuit 11[1] the abnormality detection signal indicating that the overcurrent abnormality is detected. Similarly, the abnormality detection circuit 14[2] according to the second case (see FIG. 11) determines that the overcurrent abnormality has occurred, when the value of the output current Iout[2] that is the overcurrent threshold value I_{TH} or more is detected at time point tB₃, and outputs to the control circuit 11[2] the abnormality detection signal indicating that the overcurrent abnormality is detected.

Alternatively, in each switch device 10, the abnormality detection circuit 14 may determine that the overcurrent abnormality has occurred, when the value of the output current Iout has continued to be the overcurrent threshold value I_{TH} or more for a predetermined time period Δt1. In this case, time point t_{A3} related to the first case is time point when the value of the output current Iout[1] has continued to be the overcurrent threshold value I_{TH} or more for the predetermined time period Δt1 (see FIG. 9), and the abnormality detection circuit 14[1] according to the first case may determine at time point t_{A3} that the overcurrent abnormality has occurred, and may output to the control circuit 11[1] the abnormality detection signal indicating that the overcurrent abnormality is detected. Similarly, time point t_{B3} related to the second case is time point when the value of the output current Iout[2] has continued to be the overcurrent threshold value I_{TH} or more for the predetermined time period Δt1 (see FIG. 11), and the abnormality detection circuit 14[2] according to the second case may determine at time point t_{B3} that the overcurrent abnormality has occurred, and may output to the control circuit 11[2] the abnormality detection signal indicating that the overcurrent abnormality is detected.

The control circuit 11[1] according to the first case performs the first abnormality response operation when the abnormality detection circuit 14[1] has detected the overcurrent abnormality. The control circuit 11[2] according to the second case performs the first abnormality response operation when the abnormality detection circuit 14[2] has detected the overcurrent abnormality. As described above, in the first abnormality response operation, the off latch control, the intermittent ON/OFF control, or the current restriction control can be performed.

If the off latch control is performed in the first abnormality response operation according to the first case, the control circuit 11[1] maintains the output transistor M1[1] to be OFF state, without depending on the control signal Sin[1](i.e., even if the control signal Sin[1] is at high level), during time points t_{A3} and t_{A4}.

If the intermittent ON/OFF control is performed in the first abnormality response operation according to the first case, the control circuit 11[1] switches the output transistor M1[1] from ON to OFF at time point t_{A3}, maintains the output transistor M1[1] to be OFF for a predetermined cool down time period Δt2, and restores ON of the output transistor M1[1]. After restoring ON of the output transistor M1[1], if the value of the output current Iout[1] is the overcurrent threshold value I_{TH} or more, the output transistor M1[1] is maintained to be OFF again for the predetermined cool down time period Δt2, and the above operation is repeated. After the intermittent ON/OFF control is started, if the value of the output current Iout[1] when the output transistor M1[1] is ON is maintained to be less than the overcurrent threshold value I_{TH}, the control circuit 11[1] may maintain the output transistor M1[1] to be ON, on the precondition that the control signal Sin[1] is at high level.

If the current restriction control is performed in the first abnormality response operation according to the first case, the control circuit 11[1] maintains the output transistor M1[1] to be ON state, while it adjusts the gate voltage of the output transistor M1[1] using a detection result of the current sensor, so that the value of the output current Iout[1] can be restricted to be the predetermined limit value I_{LIM} or less.

If the off latch control is performed in the first abnormality response operation according to the second case, the control circuit 11[2] maintains the output transistor M1[2] to be OFF state, without depending on the control signal Sin[2](i.e., even if the control signal Sin[2] is at high level), during time points t_{B3} and t_{B4}.

If the intermittent ON/OFF control is performed in the first abnormality response operation according to the second case, the control circuit 11[2] switches the output transistor M1[2] from ON to OFF at time point t_{B3}, maintains the output transistor M1[2] to be OFF for the predetermined cool down time period Δt2, and restores ON of the output transistor M1[2]. After restoring ON of the output transistor M1[2], if the value of the output current Iout[2] is the overcurrent threshold value I_{TH} or more, the output transistor M1[2] is maintained to be OFF again for the predetermined cool down time period Δt2, and the above operation is repeated. After the intermittent ON/OFF control is started, if the value of the output current Iout[2] when the output transistor M1[2] is ON is maintained to be less than the overcurrent threshold value I_{TH}, the control circuit 11[2] may maintain the output transistor M1[2] to be ON, on the precondition that the control signal Sin[2] is at high level.

If the current restriction control is performed in the first abnormality response operation according to the second case, the control circuit 11[2] maintains the output transistor M1[2] to be ON state, while it adjusts the gate voltage of the output transistor M1[2] using a detection result of the current sensor, so that the value of the output current Iout[2] can be restricted to be the predetermined limit value I_{LIM} or less.

### Second Practical Example

A second practical example is described. The plurality of types of abnormalities that can be detected by the abnormality detection circuit 14 include the temperature abnormality. In the second practical example, it is supposed that the abnormality that can be detected by the abnormality detection circuit 14 is the temperature abnormality.

In each switch device 10, the abnormality detection circuit 14 includes a temperature protection circuit 14a that detects temperature Tj (see FIG. 14). The temperature Tj is temperature at a predetermined first temperature measurement point in the switch device 10, and the first temperature measurement point is a position at which the output transistor M1 is disposed in the switch device 10. In other words, the temperature Tj is temperature of the output transistor M1. More specifically, the temperature Tj is temperature at a predetermined point of the semiconductor constituting the output transistor M1 and corresponds to junction temperature of the output transistor M1. However, the temperature Tj may be temperature at an arbitrary predetermined point in the switch device 10, which is different from the temperature of the output transistor M1. The temperature protection circuit 14a generates and outputs a signal S_{TSD} corresponding to the detected temperature Tj. The signal S_{TSD} is a binary signal having a value of “0” or “1”. The signal S_{TSD} is supplied to the control circuit 11.

FIG. 15 is a timing chart illustrating a relationship between the temperature Tj and the signal S_{TSD}. In a state where the temperature Tj is sufficiently low, the signal S_{TSD} has a value of “0”. When the state where “Tj<T_{TSD}_H” holds is changed to the state where “Tj≥T_{TSD}_H” holds, along with an increase in the temperature Tj from the state where the signal S_{TSD} has a value of “0”, the value of the signal S_{TSD} is changed from “0” to “1”, and after that, when the state where “Tj≥T_{TSD}_L” holds is changed to the state where “Tj<T_{TSD}_L” holds along with a decrease in the temperature Tj, the value of the signal S_{TSD} is changed from “1” to “0”. Here, T_{TSD}_H and T_{TSD}_L indicate a predetermined protection temperature (protection start temperature) and a protection release temperature, respectively. The protection temperature T_{TSD}_H is higher than the protection release temperature T_{TSD}_L. For instance, the protection temperature T_{TSD}_H and the protection release temperature T_{TSD}_L are 175 degrees Celsius and 155 degrees Celsius, respectively. In this way, the temperature protection circuit 14a is configured to switch the value of the signal S_{TSD} from “0” to “1”, when the temperature Tj increases to reach the predetermined protection temperature T_{TSD}_H.

In each switch device 10, the abnormality detection circuit 14 determines that the temperature abnormality has occurred when the value of the signal S_{TSD} is changed from “0” to “1”. The temperature abnormality based on the value of the signal S_{TSD} is particularly referred to as a first temperature abnormality. Therefore, the abnormality detection circuit 14[1] according to the first case (see FIG. 9) determines that the first temperature abnormality has occurred, when receiving information that the value of the signal S_{TSD} in the abnormality detection circuit 14[1] is changed from “0” to “1” at time point t_{A3}, and outputs to the control circuit 11[1] the signal S_{TSD} of “1” as the abnormality detection signal indicating that the first temperature abnormality is detected. Similarly, the abnormality detection circuit 14[2] according to the second case (see FIG. 11) determines that the first temperature abnormality has occurred, when receiving information that the value of the signal S_{TSD} in the abnormality detection circuit 14[2] is changed from “0” to “1” at time point t_{B3}, and outputs to the control circuit 11[2] the signal S_{TSD} of “1” as the abnormality detection signal indicating that the first temperature abnormality is detected.

The control circuit 11[1] according to the first case performs the first abnormality response operation when the abnormality detection circuit 14[1] has detected the first temperature abnormality. The control circuit 11[2] according to the second case performs the first abnormality response operation when the abnormality detection circuit 14[2] has detected the first temperature abnormality. In the first abnormality response operation corresponding to detection of the first temperature abnormality, the off latch control or the intermittent ON/OFF control is performed.

When the off latch control is performed in the first abnormality response operation according to the first case, the control circuit 11[1] maintains the output transistor M1[1] to be OFF state during time points t_{A3} and t_{A4}, without depending on the control signal Sin[1](i.e., even if the control signal Sin[1] is at high level), and without depending on the value of the signal S_{TSD} in the abnormality detection circuit 14[1](i.e., even if “0” of the value of the signal S_{TSD} is restored).

When the intermittent ON/OFF control is performed in the first abnormality response operation according to the first case, the control circuit 11[1] switches the output transistor M1[1] from ON to OFF at time point t_{A3} and then monitors the signal S_{TSD} supplied from the temperature protection circuit 14a in the abnormality detection circuit 14[1]. If the value of the signal S_{TSD} is restored from “1” to “0”, the control circuit 11[1] switches the output transistor M1[1] from OFF to ON, on the precondition that the control signal Sin[1] has high level. After that, when the value of the signal S_{TSD} is changed from “0” to “1”, the control circuit 11[1] restores OFF of the output transistor M1[1] again. After that, the same processes are repeated.

When the off latch control is performed in the first abnormality response operation according to the second case, the control circuit 11[2] maintains the output transistor M1[2] to be OFF state during time points t_{B3} and t_{B4}, without depending on the control signal Sin[2](i.e., even if the control signal Sin[2] is at high level), and without depending on the value of the signal S_{TSD} in the abnormality detection circuit 14[2](i.e., even if “0” of the value of the signal S_{TSD} is restored).

When the intermittent ON/OFF control is performed in the first abnormality response operation according to the second case, the control circuit 11[2] switches the output transistor M1[2] from ON to OFF at time point t_{B3} and then monitors the signal S_{TSD} supplied from the temperature protection circuit 14a in the abnormality detection circuit 14[2]. When the value of the signal S_{TSD} is restored from “1” to “0”, the control circuit 11[2] switches the output transistor M1[2] from OFF to ON, on the precondition that the control signal Sin[2] has high level. After that, when the value of the signal S_{TSD} is changed from “0” to “1”, the control circuit 11[2] restores OFF of the output transistor M1[2] again. After that, the same processes are repeated.

### Third Practical Example

A third practical example is described. Similarly to the second practical example, it is supposed in the third practical example that the abnormality that can be detected by the abnormality detection circuit 14 is the temperature abnormality.

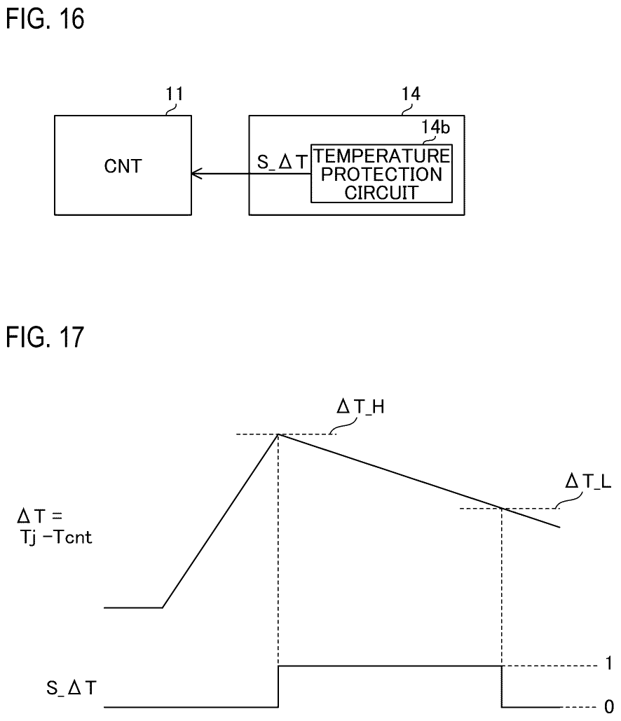

In each switch device 10, the abnormality detection circuit 14 includes a temperature protection circuit 14b that detects a difference between the temperature Tj and a temperature Tcnt (see FIG. 16). The temperature Tj is as described above in the second practical example. The temperature Tcnt is temperature at a predetermined second temperature measurement point in the switch device 10. The second temperature measurement point is a point apart from the output transistor M1. For instance, the temperature Tcnt may be temperature of the control circuit 11. In any case, the second temperature measurement point is different from the first temperature measurement point described in the second practical example (the measurement point of the temperature Tj). A temperature difference between the temperatures Tj and Tcnt is referred to as a temperature difference ΔT in the following description. However, the temperature difference ΔT is a level of the temperature Tj with respect to the temperature Tcnt, and hence the temperature difference ΔT is expressed by “ΔT=Tj−Tcnt”. The temperature protection circuit 14b generates and outputs a signal S_ΔT corresponding to the detected temperature difference ΔT. The signal S_ΔT is a binary signal having a value of “0” or “1”. The signal S_ΔT is supplied to the control circuit 11.

FIG. 17 is a timing chart indicating a relationship between the temperature difference ΔT and the signal S_ΔT. In a state where the temperature difference ΔT is sufficiently small, the signal S_ΔT has a value of “0”. When the state where “ΔT<ΔT_H” holds is changed to the state where “ΔT≥ΔT_H” holds, along with an increase of the temperature difference ΔT from the state where the signal S_ΔT has a value of “0”, the value of the signal S_ΔT is changed from “0” to “1”. After that, when the state where “ΔT≥ΔT_L” holds is changed to the state where “ΔT<ΔT_L” holds, along with a decrease of the temperature difference ΔT, the value of the signal S_ΔT is changed from “1” to “0”. Here, ΔT_H and ΔT_L are a predetermined protection temperature difference (protection start temperature difference) and a protection release temperature difference, respectively. The protection temperature difference ΔT_H is larger than the protection release temperature difference ΔT_L. For instance, the protection temperature difference ΔT_H and the protection release temperature difference ΔT_L are 80 degrees Celsius and 45 degrees Celsius, respectively. In this way, the temperature protection circuit 14b is configured to switch the value of the signal S_ΔT from “0” to “1”, when the temperature difference ΔT increases to reach the predetermined protection temperature difference ΔT_H.

In each switch device 10, when the value of the signal S_ΔT is changed from “0” to “1”, the abnormality detection circuit 14 determines that the temperature abnormality has occurred. The temperature abnormality based on the value of the signal S_ΔT is particularly referred to as a second temperature abnormality. Therefore, the abnormality detection circuit 14[1] according to the first case (see FIG. 9) determines that the second temperature abnormality has occurred, when the value of the signal S_ΔT in the abnormality detection circuit 14[1] is changed from “0” to “1” at time point t_{A3}, and outputs to the control circuit 11[1] the signal SAT of “1” as the abnormality detection signal indicating that the second temperature abnormality has been detected. Similarly, the abnormality detection circuit 14[2] according to the second case (see FIG. 11) determines that the second temperature abnormality has occurred, when the value of the signal S_ΔT in the abnormality detection circuit 14[2] is changed from “0” to “1” at time point t_{B3}, and outputs to the control circuit 11[2] the signal S_ΔT of “1” as the abnormality detection signal indicating that the second temperature abnormality has been detected.

The control circuit 11[1] according to the first case performs the first abnormality response operation, when the abnormality detection circuit 14[1] has detected the second temperature abnormality. The control circuit 11[2] according to the second case performs the first abnormality response operation, when the abnormality detection circuit 14[2] has detected the second temperature abnormality. In the first abnormality response operation corresponding to the second temperature abnormality detection, the off latch control or the intermittent ON/OFF control is performed.

When the off latch control is performed in the first abnormality response operation according to the first case, the control circuit 11[1] maintains the output transistor M1[1] to be OFF state during time points t_{A3} and t_{A4}, without depending on the control signal Sin[1](i.e., even if the control signal Sin[1] is at high level), and without depending on the value of the signal S_ΔT in the abnormality detection circuit 14[1](i.e., even if the value of the signal S_ΔT is restored to “0”).

When the intermittent ON/OFF control is performed in the first abnormality response operation according to the first case, the control circuit 11[1] switches the output transistor M1[1] from ON to OFF at time point t_{A3} and then monitors the signal S_ΔT supplied from the temperature protection circuit 14b in the abnormality detection circuit 14[1]. When the value of the signal S_ΔT is restored from “1” to “0”, the control circuit 11[1] switches the output transistor M1[1] from OFF to ON, on the precondition that the control signal Sin[1] has high level. After that, when the value of the signal S_ΔT is changed from “0” to “1”, the control circuit 11[1] restores OFF of the output transistor M1[1] again. After that, the same processes are repeated.

When the off latch control is performed in the first abnormality response operation according to the second case, the control circuit 11[2] maintains the output transistor M1[2] to be OFF state during time points t_{B3} and t_{B4}, without depending on the control signal Sin[2](i.e., even if the control signal Sin[2] is at high level), and without depending on the value of the signal S_ΔT in the abnormality detection circuit 14[2](i.e., even if the value of the signal S_ΔT is restored to “0”).

When the intermittent ON/OFF control is performed in the first abnormality response operation according to the second case, the control circuit 11[2] switches the output transistor M1[2] from ON to OFF at time point t_{B3}, and then monitors the signal S_ΔT supplied from the temperature protection circuit 14b in the abnormality detection circuit 14[2]. When the value of the signal S_ΔT is restored from “1” to “0”, the control circuit 11[2] switches the output transistor M1[2] from OFF to ON, on the precondition that the control signal Sin[2] has high level. After that, when the value of the signal S_ΔT is changed from “0” to “1”, the control circuit 11[2] restores OFF of the output transistor M1[2] again. After that, the same processes are repeated.

### Fourth Practical Example

A fourth practical example is described. It may be possible to configure each switch device 10 to be capable of arbitrarily adjusting the above overcurrent threshold value I_{TH}. For instance, a plurality of threshold values are set as candidates of the overcurrent threshold value I_{TH} in the control circuit 11, and one of the threshold values is designated by a command signal from the MCU 20. In this case, when receiving the command signal from the MCU 20, the control circuit 11 sets one of the threshold values to the overcurrent threshold value I_{TH} in accordance with designation by the command signal. Alternatively, it may be possible to dispose an adjustment terminal as one of the external terminals on the switch device 10, and to connect an adjustment resistor for adjusting the overcurrent threshold value I_{TH} between the adjustment terminal and the ground in the outside of the switch device 10. In this case, the control circuit 11 should have a function of setting and changing the overcurrent threshold value I_{TH} in accordance with a resistance value of the adjustment resistor. As the switch device 10 is configured to be capable of adjusting the overcurrent threshold value I_{TH}, the overcurrent protection can work at a current value that is appropriate for the load drive system SYS.

It is also possible to design, manufacture, and market a plurality of types of switch devices 10 having different ON resistances of the output transistor M1. In this case, if the overcurrent threshold value I_{TH} is adjustable, it is also effective for reducing the number of types of the switch device 10 (for reducing the number of lineups of the ON resistance to be prepared).

However, it is not essential to allow the switch device 10 to have the function of adjusting the overcurrent threshold value I_{TH}. If the switch device 10 is not allowed to have the function of adjusting the overcurrent threshold value I_{TH}, a communication function for sending and receiving the above command signal can be omitted, and the above-mentioned adjustment terminal and adjustment resistor are also not necessary. In this case, it is possible to arrange the overcurrent threshold value I_{TH} to be relatively high value. In other words, for example, it is supposed that there is a designed structure in which a current of 10 A is supplied to the load LD in a steady state. Then, in the steady state, a current of 5 A flows in each of the output transistors M1[1] and M1[2]. In this structure, it is preferred to use the switch devices 10 in which the overcurrent threshold value I_{TH} is set larger than the supply current to the load LD in the steady state (e.g., is set to 12 A). Then, if an abnormality is detected in one of the switch devices 10 and the output transistor M1 of the other switch device 10 is latched to be OFF, the one of the switch devices 10 can continue to supply the current (10 A) necessary for the load LD, utilizing the current restriction control or the like. When receiving the diagnosis signal Sst of low level, the MCU 20 can issue a warning to the driver of the vehicle VHCL, and the driver who receives the warning can respond thereto by stopping the vehicle VHCL on a road shoulder, for example. Even if the system is originally designed to supply the current to the load LD by cooperation between the two switch devices 10, it may not cause a problem to drive the load LD by only the above one of the switch devices 10, for a short time until the vehicle VHCL is stopped on a road shoulder.

### Fifth Practical Example

A fifth practical example is described.

Considering to describe in detail, the above description of operation of the load drive system SYS is mainly supposed that “n=2” holds. The symbol n corresponds to the total number of the switch devices 10 (the total number of the output transistors M1 connected in parallel) (see FIG. 7). However, it may be possible that “n≥3” holds. For instance, if “n=3” holds, a switch device 10[3] has the same operation as the switch device 10[2] in the above first case (FIGS. 9 and 10), and the switch device 10[3] has the same operation as the switch device 10[1] in the above second case (FIGS. 11 and 12).

The load drive system SYS includes a switch system. The switch system is configured to include the switch devices 10[1] to 10[n].

In the structure exemplified in FIG. 1 or the like, the switch device 10 is used as a so-called high side switch, but it may be possible to use the switch device 10 as a so-called low side switch. In other words, the load LD may be inserted in series to the input wiring W1. In this case, in each switch device 10, the terminal VBB functions as a load connection terminal, and the output terminal OUT is directly connected to the ground via the output wiring W2 (or the ground terminal GND is used as the output terminal OUT). In addition, the power supply voltage VCC should be supplied separately to the switch terminal 10, as the power supply voltage for driving the switch device 10 (an external terminal for receiving the power supply voltage VCC should be added to each switch terminal 10). If each switch device 10 is used as the so-called low side switch, the charge pump circuit 13 is not necessary, and the internal power supply circuit 16 should generate the internal power supply voltage Vreg from the power supply voltage VCC.

This embodiment shows the example in which the switch device 10 is applied to the vehicle VHCL, but the application of the switch device 10 is arbitrary without being limited to the vehicle VHCL. For instance, the switch device 10 may be mounted in any industrial machine or any home electric appliance.

As for an arbitrary signal or voltage, a relationship between high level and low level thereof can be inverted from that described above, in the form where the spirit of the above description is not impaired.

The type of channel of the field effect transistor (FET) shown in the above embodiment is merely an example. The type of channel of any FET can be changed between P-channel type and N-channel type, in the form where the spirit of the above description is not impaired.

The above arbitrary transistor may be any type of transistor unless any inconvenience arises. For instance, the above arbitrary transistor described as a MOSFET may be replaced with a junction type FET, an insulated gate bipolar transistor (IGBT), or a bipolar transistor, unless any inconvenience arises. An arbitrary transistor has a first electrode, a second electrode, and a control electrode. In an FET, one of the first and second electrodes is the drain while the other is the source, and the control electrode is the gate. In an IGBT, one of the first and second electrodes is the collector while the other is the emitter, and the control electrode is the gate. In a bipolar transistor that is not classified as an IGBT, one of the first and second electrode is the collector while the other is the emitter, and the control electrode is the base.

The embodiment of the present disclosure can be appropriately and variously modified within the scope of the technical concept recited in the claims. The embodiment described above is merely an example of the embodiment of the present disclosure, and meanings of terms in the present disclosure and of structural elements are not limited to those described in the above embodiment. The specific numeric values shown in the above description are merely examples, and can be changed to various numeric values as a matter of course.

### Additional Notes

As for the present disclosure in which specific structural examples are shown in the above embodiment, additional notes are described below.

A switch device (10) according to one aspect of the present disclosure has a structure (first structure) including an input terminal (VBB), an output terminal (OUT), a diagnostic terminal (ST), an output transistor (M1) disposed between the input terminal and the output terminal, a control circuit (11) configured to control the output transistor to be ON or OFF in accordance with a control signal (Sin) supplied to the switch device, an abnormality detection circuit (14) configured to detect an abnormality in the switch device, and a diagnosis output circuit (15) configured to control a state of the diagnostic terminal. When an abnormality is detected after a reference period while an abnormality is not detected and the output transistor is set to ON in accordance with the control signal (a period between time points t_{A1} and t_{A2} or a period between time points t_{B1} and t_{B2}), the control circuit performs a first abnormality response operation, in which the control circuit switches the output transistor from ON to OFF, or restricts a value of current flowing in the output transistor to a limit value or less, and switches a state of the diagnostic terminal from a first state (Hi-Z state) to a second state (Lo-Z state) using the diagnosis output circuit, so as to switch a voltage level of the diagnostic terminal from a first level (high level) to a second level (low level), and after the reference period, when an abnormality is not detected and the voltage level of the diagnostic terminal is changed from the first level to the second level, the control circuit performs a second abnormality response operation, in which the output transistor is switched from ON to OFF.

When forming a switch device group consisting of a plurality of switch devices whose diagnostic terminals are connected to each other, a state where an abnormality is detected in a specific switch device corresponds to a state where the abnormality has occurred in the switch device group. In this case, if another switch device continues its operation independently of the specific switch device in which the abnormality has occurred, an unexpected trouble may occur resulting in an undesired situation (operation of the entire switch device group becomes unstable, i.e., stability of operation of the switch device group is deteriorated). If the first structure is used to form the switch device group, when an abnormality is detected in a specific switch device, the fact is informed to other switch devices via the diagnostic terminals so that the output transistors of the other switch devices can be switched to OFF. In other words, the other switch device does not continue its operation independently of the specific switch device in which the abnormality has occurred, and the fear described above is cast aside (the first structure can bring such the action). In addition, a level of the wiring connecting the diagnostic terminals can be given to an external control device, and in this case, only by monitoring the level of the wiring with the external control device, the state of the switch device group can be collectively grasped.

The switch device having the above first structure may have a structure (second structure), in which in the second abnormality response operation, the control circuit switches the output transistor from ON to OFF and then maintains the output transistor to be OFF.

The switch device having the above first structure (see FIG. 10 or 12) may have a structure (third structure), in which in the second abnormality response operation, the control circuit switches the output transistor from ON to OFF and then maintains the output transistor to be OFF until an error release condition is satisfied. The error release condition is satisfied when a level of the control signal is changed from an ON command level (high level) instructing to set the output transistor to be ON to an OFF command level (low level) instructing to set the output transistor to be OFF. In the second abnormality response operation, the control circuit switches the output transistor from ON to OFF and then responds to the level of the control signal being set to the ON command level after the error release condition is satisfied, so as to switch the output transistor from OFF to ON. Note that it is sufficient that the ON command level and the OFF command level are different from each other, and a high-low relationship between them does not matter.

The switch device having any one of the above first to third structures may have a structure (fourth structure), in which the diagnostic terminal is configured to be connected to a diagnosis wiring (W4) in the outside of the switch device, the diagnostic terminal has an input impedance larger in the first state (the Hi-Z state) than in the second state (the Lo-Z state), viewed from the diagnosis wiring. When the diagnosis output circuit sets the state of the diagnostic terminal to the second state, a diagnosis current is generated through the diagnostic terminal and the diagnosis wiring, so that the voltage level of the diagnostic terminal has the second level. When the diagnosis output circuit sets the state of the diagnostic terminal to the first state, the diagnosis current is cut off, so that an action of the diagnosis output circuit to set the voltage level of the diagnostic terminal to the second level is stopped.

The switch device having any one of the above first to third structures may have a structure (fifth structure), in which the diagnostic terminal is configured to be connected to a diagnosis wiring (W4) in the outside of the switch device, while the diagnosis wiring is connected to an application terminal (51) of the first level voltage via a pull-up resistor (Ra). The diagnosis output circuit includes a diagnosis switching element (15a) disposed between the diagnostic terminal and a ground. The second state is a state for setting the diagnosis switching element to ON, so as to generate a diagnosis current flowing from the application terminal through the pull-up resistor, the diagnostic terminal, and the diagnosis switching element, so as to set the voltage level of the diagnostic terminal to the second level lower than the first level. The first state is a state of setting the diagnosis switching element to OFF, and when the diagnosis output circuit sets the state of the diagnostic terminal to the first state, the diagnosis current through the diagnosis output circuit is cut off, so that an action of the diagnosis output circuit to set the voltage level of the diagnostic terminal to the second level is stopped.

The switch device having any one of the above first to fifth structures may have a structure (sixth structure), in which the abnormality includes an overcurrent abnormality, and the abnormality detection circuit compares a value of an output current (Iout) flowing through the output transistor with a predetermined overcurrent threshold value (I_{TH}), so as to determine presence or absence of the overcurrent abnormality. When the overcurrent abnormality is detected after the reference period, the control circuit performs the first abnormality response operation, and in the first abnormality response operation based on the detection of the overcurrent abnormality, the control circuit switches the output transistor from ON to OFF or restricts the value of current flowing in the output transistor to the limit value or less.

The switch device having any one of the above first to sixth structures may have a structure (seventh structure), in which the abnormality includes an temperature abnormality, and the abnormality detection circuit compares temperature (Tj) of the output transistor with predetermined protection temperature (T_{TSD}_H), or compares a temperature difference (ΔT=Tj−Tcnt) between the temperature of the output transistor and other temperature in the switch device with a predetermined protection temperature difference (ΔT_H), so as to determine presence or absence of the temperature abnormality. When the temperature abnormality is detected after the reference period, the control circuit performs the first abnormality response operation, and in the first abnormality response operation based on the temperature abnormality detection, the control circuit switches the output transistor from ON to OFF.

A load drive system (SYS) according to one aspect of the present disclosure has a structure (eighth structure) including a plurality of switch devices (10) having any one of the above first to seventh structures, and an external control device (20) configured to supply the control signal to each switch device. The plurality of switch devices has a plurality of output transistors (M1[1] to M1[n]) connected in parallel to each other, so that current is supplied to a load (LD) through a parallel circuit of the plurality of output transistors. The plurality of switch devices have a plurality of diagnostic terminals (ST[1] to ST[n]) connected commonly to a diagnosis wiring (W4), which is connected to the external control device.

The above load drive system can be designed so that a switch device group consisting of the plurality of switch devices drives the load. In this case, a state where an abnormality is detected in a specific switch device corresponds to a state where the abnormality has occurred in the switch device group. In the state where the abnormality has occurred in the switch device group (i.e., in a state where the load is not driven as designed), if another switch device continues its operation independently of the specific switch device in which the abnormality has occurred, an unexpected trouble may occur resulting in an undesired situation (operation of the entire switch device group becomes unstable, i.e., stability of operation of the switch device group is deteriorated). According to the above load drive system, when an abnormality is detected in an specific switch device, the fact is informed to other switch devices via the diagnostic terminals so that the output transistors of the other switch devices can be switched to OFF. In other words, the other switch device does not continue its operation independently of the specific switch device in which the abnormality has occurred, and the fear described above is cast aside. In addition, because the diagnosis wiring connecting the diagnostic terminals is connected to the external control device, only by monitoring the level of the diagnosis wiring with the external control device, the state of the switch device group can be collectively grasped.

The load drive system having the above eighth structure may have a structure (ninth structure), in which the reference period is a period while no abnormality is detected in each of the plurality of switch devices and the output transistor is set to ON in accordance with the control signal in each of the plurality of switch devices. When an abnormality is detected in a specific switch device (e.g., 10[1]) included in the plurality of switch devices after the reference period, the control circuit of the specific switch device performs the first abnormality response operation, so that a voltage level of the diagnosis wiring is switched from the first level to the second level using the diagnosis output circuit of the specific switch device, and responding to the switching, a switch device (e.g., 10[2]) other than the specific switch device among the plurality of switch devices performs the second abnormality response operation.

A switch system according to one aspect of the present disclosure has a structure (tenth structure) including a plurality of switch devices (10) having any one of the above first to seventh structures, in which the plurality of switch devices have a plurality of output transistor (M1[1] to M1[n]) connected in parallel to each other, and the plurality of switch devices have a plurality of diagnostic terminals (ST[1] to ST[n]) connected commonly to a diagnosis wiring (W4).

The switch system having the above eighth structure may have a structure (eleventh structure), in which the reference period is a period while no abnormality is detected in each of the plurality of switch devices and the output transistor is set to ON in accordance with the control signal in each of the plurality of switch devices. When an abnormality is detected in a specific switch device (e.g., 10[1]) included in the plurality of switch devices after the reference period, the control circuit of the specific switch device performs the first abnormality response operation, so that a voltage level of the diagnostic wiring is switched from the first level to the second level using the diagnosis output circuit of the specific switch device, and responding to the switching, a switch device (e.g., 10[2]) other than the specific switch device among the plurality of switch devices performs the second abnormality response operation.

What is claimed is:

1. A switch device comprising an input terminal, an output terminal, a diagnostic terminal, an output transistor disposed between the input terminal and the output terminal, a control circuit configured to control the output transistor to be ON or OFF in accordance with a control signal supplied to the switch device, an abnormality detection circuit configured to detect an abnormality in the switch device, and a diagnosis output circuit configured to control a state of the diagnostic terminal, wherein
when an abnormality is detected after a reference period while an abnormality is not detected and the output transistor is set to ON in accordance with the control signal, the control circuit performs a first abnormality response operation, in which the control circuit switches the output transistor from ON to OFF, or restricts a value of current flowing in the output transistor to a limit value or less, and switches a state of the diagnostic terminal from a first state to a second state using the diagnosis output circuit, so as to switch a voltage level of the diagnostic terminal from a first level to a second level, and
after the reference period, when the abnormality is not detected and the voltage level of the diagnostic terminal is changed from the first level to the second level, the control circuit performs a second abnormality response operation, in which the output transistor is switched from ON to OFF.

2. The switch device according to claim 1, wherein in the second abnormality response operation, the control circuit switches the output transistor from ON to OFF and then maintains the output transistor to be OFF.

3. The switch device according to claim 1, wherein
in the second abnormality response operation, the control circuit switches the output transistor from ON to OFF, and then maintains the output transistor to be OFF until an error release condition is satisfied,
the error release condition is satisfied when a level of the control signal is changed from an ON command level instructing to set the output transistor to be ON to an OFF command level instructing to set the output transistor to be OFF, and
in the second abnormality response operation, the control circuit switches the output transistor from ON to OFF and then responds to the level of the control signal being set to the ON command level after the error release condition is satisfied, so as to switch the output transistor from OFF to ON.

4. The switch device according to claim 1, wherein
the diagnostic terminal is configured to be connected to a diagnosis wiring in the outside of the switch device,
the diagnostic terminal has an input impedance larger in the first state than in the second state, viewed from the diagnosis wiring,
when the diagnosis output circuit sets the state of the diagnostic terminal to the second state, a diagnosis current is generated through the diagnostic terminal and the diagnosis wiring, so that the voltage level of the diagnostic terminal has the second level, and
when the diagnosis output circuit sets the state of the diagnostic terminal to the first state, the diagnosis current is cut off, so that an action of the diagnosis output circuit to set the voltage level of the diagnostic terminal to the second level is stopped.

5. The switch device according to claim 1, wherein
the diagnostic terminal is configured to be connected to a diagnosis wiring in the outside of the switch device, while the diagnosis wiring is connected to an application terminal of the first level voltage via a pull-up resistor,
the diagnosis output circuit includes a diagnosis switching element disposed between the diagnostic terminal and a ground,
the second state is a state of setting the diagnosis switching element to ON, so as to generate a diagnosis current flowing from the application terminal through the pull-up resistor, the diagnostic terminal, and the diagnosis switching element, so as to set the voltage level of the diagnostic terminal to the second level lower than the first level, and
the first state is a state of setting the diagnosis switching element to OFF, and when the diagnosis output circuit sets the state of the diagnostic terminal to the first state, the diagnosis current through the diagnosis output circuit is cut off, so that an action of the diagnosis output circuit to set the voltage level of the diagnostic terminal to the second level is stopped.

6. The switch device according to claim 1, wherein
the abnormality includes an overcurrent abnormality, and the abnormality detection circuit compares a value of an output current flowing through the output transistor with a predetermined overcurrent threshold value, so as to determine presence or absence of the overcurrent abnormality, and
when the overcurrent abnormality is detected after the reference period, the control circuit performs the first abnormality response operation, and in the first abnormality response operation based on the detection of the overcurrent abnormality, the control circuit switches the output transistor from ON to OFF or restricts the value of current flowing in the output transistor to the limit value or less.

7. The switch device according to claim 1, wherein
the abnormality includes a temperature abnormality, and the abnormality detection circuit compares temperature of the output transistor with predetermined protection temperature, or compares a temperature difference between the temperature of the output transistor and other temperature in the switch device with a predetermined protection temperature difference, so as to determine presence or absence of the temperature abnormality, and
when the temperature abnormality is detected after the reference period, the control circuit performs the first abnormality response operation, and in the first abnormality response operation based on the temperature abnormality detection, the control circuit switches the output transistor from ON to OFF.

8. A load drive system comprising a plurality of switch devices according to claim 1, and an external control device configured to supply the control signal to each switch device, wherein
the plurality of switch devices has a plurality of output transistors connected in parallel to each other, so that current is supplied to a load through a parallel circuit of the plurality of output transistors, and
the plurality of switch devices have a plurality of diagnostic terminals connected commonly to a diagnosis wiring, which is connected to the external control device.

9. The load drive system according to claim 8, wherein
the reference period is a period while no abnormality is detected in each of the plurality of switch devices and the output transistor is set to ON in accordance with the control signal in each of the plurality of switch devices, and
when an abnormality is detected in a specific switch device included in the plurality of switch devices after the reference period, the control circuit of the specific switch device performs the first abnormality response operation, so that a voltage level of the diagnosis wiring is switched from the first level to the second level using the diagnosis output circuit of the specific switch device, and responding to the switching, a switch device other than the specific switch device among the plurality of switch devices performs the second abnormality response operation.

10. A switch system comprising a plurality of switch devices according to claim 1, wherein the plurality of switch devices has a plurality of output transistors connected in parallel to each other, and the plurality of switch devices have a plurality of diagnostic terminals connected commonly to a diagnosis wiring.

11. The switch system according to claim 10, wherein
the reference period is a period while no abnormality is detected in each of the plurality of switch devices and the output transistor is set to ON in accordance with the control signal in each of the plurality of switch devices, and
when an abnormality is detected in a specific switch device included in the plurality of switch devices after the reference period, the control circuit of the specific switch device performs the first abnormality response operation, so that the voltage level of the diagnostic wiring is switched from the first level to the second level using the diagnosis output circuit of the specific switch device, and responding to the switching, a switch device other than the specific switch device among the plurality of switch devices performs the second abnormality response operation.
